(19) United States
(12) Patent Application Publication
(10) Pub. No.: US 2011/0215325 A1
(43) Pub. Date: Sep. 8, 2011

(54) METHOD FOR MANUFACTURING SEMICONDUCTOR DEVICE

(75) Inventors: Shunpei YAMAZAKI, Setagaya (JP); Kunihiko SUZUKI, Atsugi (JP)

(73) Assignee: SEMICONDUCTOR ENERGY LABORATORY CO., LTD., Atsugi (JP)

(21) Appl. No.: 13/034,727

(22) Filed: Feb. 25, 2011

(30) Foreign Application Priority Data
Mar. 5, 2010 (JP) 2010-049602

(51) Int. Cl. H01L 29/786; H01L 21/34

(52) U.S. Cl. 257/57; 438/104; 257/E29.296; 257/E21.459

(57) ABSTRACT

A highly purified oxide semiconductor layer is formed in such a manner that a substance that firmly bonds during film formation to an impurity containing a hydrogen atom is introduced into a film formation chamber, the substance is reacted with the impurity containing a hydrogen atom remaining in the film formation chamber, and the substance is changed to a stable substance containing the hydrogen atom. The stable substance containing the hydrogen atom is exhausted without providing a metal atom of an oxide semiconductor layer with the hydrogen atom; therefore, a phenomenon in which a hydrogen atom or the like is taken into the oxide semiconductor layer can be prevented. As the substance that firmly bonds to the impurity containing a hydrogen atom, a substance containing a halogen element is preferable, for example.

### TECHNICAL FIELD

The present invention relates to a semiconductor device including an oxide semiconductor, and a method for manufacturing the semiconductor device. Note that here, semiconductor devices refer to general elements and devices which function utilizing semiconductor characteristics.

### BACKGROUND ART

A technique in which a transistor is formed using a semiconductor layer formed over a substrate having an insulating surface is known. For example, a technique in which a transistor is formed over a glass substrate using a thin film containing a silicon-based semiconductor material and applied to a liquid crystal display device and the like is known.

A transistor which is used in a liquid crystal display device is generally formed using a semiconductor material such as amorphous silicon or polycrystalline silicon. Although transistors including amorphous silicon have low field effect mobility, they can be formed over a larger glass substrate. Meanwhile, although transistors formed using polycrystalline silicon have high field-effect mobility, they need to be subjected to a crystallization step such as laser annealing and thus are not always suitable for larger glass substrates.

Oxide semiconductors have been attracting attention as alternative materials. As a material of the oxide semiconductor, zinc oxide or a substance containing zinc oxide is known. Thin film transistors each of which is formed using an amorphous oxide (an oxide semiconductor) having an electron carrier concentration of lower than 10¹⁸/cm³ are disclosed (Patent Documents 1 to 3).

### REFERENCE

### Patent Document

[Patent Document 1] Japanese Published Patent Application No. 2006-165527
[Patent Document 2] Japanese Published Patent Application No. 2006-165528
[Patent Document 3] Japanese Published Patent Application No. 2006-165529

### DISCLOSURE OF INVENTION

In a transistor which utilizes semiconductor characteristics, it is preferable that variation in threshold voltage caused by time degradation be small. This is because when a transistor whose variation in threshold voltage is large due to time degradation is used for a semiconductor device, the reliability of the semiconductor device is lowered. In addition, in a transistor which utilizes semiconductor characteristics, it is preferable that the off-state current be low. When a transistor whose off-state current is high is used for a semiconductor device, the power consumption of the semiconductor device is increased.

It is an object of the present invention to provide a method for manufacturing a highly reliable semiconductor device.

It is another object of the present invention to provide a method for manufacturing a semiconductor device with low power consumption.

In order to achieve the above objects, the present inventors focused their attention to the fact that in a semiconductor device in which an oxide semiconductor is used for a semiconductor layer, the concentration of impurities contained in the oxide semiconductor layer has an influence on variation in threshold voltage and an increase in off-state current. Examples of the impurities are hydrogen and a substance containing a hydrogen atom, such as water. An impurity containing a hydrogen atom provides a metal atom of an oxide semiconductor layer with a hydrogen atom; thus, an impurity level is formed.

The impurities containing a hydrogen atom contained in the oxide semiconductor can be substantially removed by first heat treatment at a relatively high temperature (e.g., 600° C.) which is performed after the oxide semiconductor is formed. However, impurities which are strongly bonded to metal contained in the oxide semiconductor (such as hydrogen and hydroxyl) are left remaining in the semiconductor layer due to a strong bonding force. When the oxide semiconductor including the residual impurities is used for a semiconductor layer, threshold voltage of a semiconductor device varies due to long-term use or exposure to light. Further, drawbacks such as an increase in off-state current and the like are incurred.

Therefore, in order to solve the above problems, impurities containing a hydrogen atom may be removed thoroughly from a film formation chamber so that a highly purified oxide semiconductor layer is formed. Specifically, the highly purified oxide semiconductor layer is formed in the following manner: a substance that firmly bonds during film formation with an impurity containing a hydrogen atom is introduced into the film formation chamber; the substance is reacted with the impurity containing a hydrogen atom which is left remaining in the film formation chamber; and the substance is changed to a stable substance containing the hydrogen atom. The stable substance containing the hydrogen atom is exhausted without providing a metal atom of an oxide semiconductor layer with the hydrogen atom; therefore, a phenomenon in which a hydrogen atom or the like is taken into the oxide semiconductor layer can be prevented. As the substance that firmly bonds to the impurity containing a hydrogen atom, a substance containing a halogen element is preferable, for example. This is because the substance containing a halogen element generates a halogen radical in plasma and thus takes a hydrogen atom from the impurity containing a hydrogen atom. Moreover, among the substances containing a halogen element, particularly, a substance containing a fluorine atom that generates a fluorine radical is preferable. This is because the bond energy between a fluorine atom and a hydrogen atom is higher than the bond energy between any of the other halogen elements and a hydrogen atom. Further, this is because the bond between a fluorine atom and a hydrogen atom is more stable than the bond between any of the other halogen elements and a hydrogen atom.

Further, the metal atom at the terminal of the oxide semiconductor included in the semiconductor layer is preferably bonded to another metal atom through oxygen. However, when a bond between a metal atom and oxygen is lost during a manufacturing process, a dangling bond of the metal atom is generated in some cases. Further, when the bond between a metal atom and oxygen is lost under the presence of an impurity containing a hydrogen atom, a bond between hydrogen and a metal atom or a bond between hydroxyl and a metal atom is generated in some cases. The dangling bond of a metal atom increases carrier density, and the bond between hydrogen and a metal atom and the bond between hydroxyl and a metal atom form an impurity level. In a semiconductor device including an oxide semiconductor layer having high carrier density, there is a tendency that the threshold voltage is normally on, and the threshold voltage might vary due to long-term use or exposure to light. Further, in a semiconductor device including an oxide semiconductor layer where an impurity level is formed, a defect such as an increase of off-state current might occur.

In order to solve the above problems, a substance that compensates the dangling bond of a metal atom which is generated during a manufacturing process may be added. Specifically, a supply source of a halogen element may be introduced into a film formation chamber. A halogen element can suppress generation of carriers or an impurity level because the halogen element bonds to and terminates the dangling bond of a metal atom contained in an oxide semiconductor layer.

In other words, according to one embodiment of the present invention, a method for manufacturing a semiconductor device includes the steps of forming a gate electrode over a substrate having an insulating surface; forming a gate insulating layer over the gate electrode; forming an oxide semiconductor layer which overlaps with the gate electrode, in contact with the gate insulating layer, in a film formation chamber into which a substance containing a halogen element is introduced in a gaseous state; performing heat treatment on the oxide semiconductor layer; forming a source electrode and a drain electrode, end portions of which overlap with the gate electrode, in contact with the oxide semiconductor layer on which the heat treatment is performed; and forming a first insulating layer which overlaps with a channel formation region of the oxide semiconductor layer and in contact with a surface of the oxide semiconductor layer.

According to another embodiment of the present invention, the method for manufacturing the semiconductor device further includes the step of heating the oxide semiconductor layer at a temperature of greater than or equal to 250° C. and less than or equal to 700° C. in nitrogen, oxygen, or a mixed gas of nitrogen and oxygen, where the content of hydrogen or water is less than or equal to 10 ppm.

According to another embodiment of the present invention, the method for manufacturing the semiconductor device further includes the step of performing slow cooling on the heated oxide semiconductor layer to a temperature of less than or equal to 200° C.

According to another embodiment of the present invention, the method for manufacturing the semiconductor device further includes the step of introducing a substance containing a fluorine atom in a gaseous state into the film formation chamber.

According to another embodiment of the present invention, a method for manufacturing a semiconductor device includes the steps of forming a source electrode and a drain electrode over a substrate having an insulating surface; forming an oxide semiconductor layer which covers end portions of the source electrode and the drain electrode in a film formation chamber into which a substance containing a halogen element is introduced in a gaseous state; performing heat treatment on the oxide semiconductor layer; forming a gate insulating layer which overlaps with the end portions of the source electrode and the drain electrode, in contact with the oxide semiconductor layer on which the heat treatment is performed; and forming a gate electrode which overlaps with the end portions of the source electrode and the drain electrode, in contact with the gate insulating layer.

According to another embodiment of the present invention, the method for manufacturing the semiconductor device further includes the step of heating the oxide semiconductor layer at a temperature of greater than or equal to 250° C. and less than or equal to 700° C. in nitrogen, oxygen, or a mixed gas of nitrogen and oxygen, where the content of hydrogen or water is less than or equal to 10 ppm.

According to another embodiment of the present invention, the method for manufacturing the semiconductor device further includes the step of performing slow cooling on the heated oxide semiconductor layer to a temperature of less than or equal to 200° C.

According to another embodiment of the present invention, the method for manufacturing the semiconductor device further includes the step of introducing a substance containing a fluorine atom in a gaseous state into the film formation chamber.

Note that the ordinal numbers such as “first” and “second” in this specification are used for convenience and do not denote the order of steps or the stacking order of layers. In addition, the ordinal numbers in this specification do not denote particular names which specify the invention.

According to a method for manufacturing a semiconductor device of the present invention, a highly purified oxide semiconductor film can be formed in such a manner that a substance containing a halogen element is introduced into a film formation chamber and a halogen radical which is generated during film formation is reacted with an impurity containing a hydrogen atom which is left remaining in the film formation chamber, so that stable halide containing the hydrogen atom is formed and exhausted. Further, the impurities which are left remaining in the semiconductor layer can be reduced by heating the semiconductor layer. In a semiconductor device including an oxide semiconductor layer where impurities which are left remaining are reduced, the variation of the threshold voltage is suppressed; thus, reliability is high.

Thus, a method for manufacturing a highly reliable semiconductor device can be provided.

In accordance with the method for manufacturing a semiconductor device of the present invention, impurities left remaining in an oxide semiconductor layer can be reduced. In a semiconductor device including the oxide semiconductor layer in which the impurities left remaining are reduced, the off-state current is reduced, and the power consumption of the semiconductor device is low.

Thus, a method for manufacturing a semiconductor device with low power consumption can be provided.

In accordance with the method for manufacturing a semiconductor device of the present invention, impurities left remaining in an oxide semiconductor layer can be reduced. In a semiconductor device including the oxide semiconductor layer in which the impurities left remaining are reduced, variation in semiconductor characteristics is small, and the mass productivity of the semiconductor device is high.

Thus, a method for manufacturing a semiconductor device with high mass productivity can be provided.

### BRIEF DESCRIPTION OF DRAWINGS

FIGS. 1A and 1B illustrate a structure of a semiconductor device according to one embodiment of the present invention.

FIGS. 2A to 2D illustrate a method for manufacturing a semiconductor device according to one embodiment of the present invention.

FIGS. 3A and 3B illustrate a structure of a semiconductor device according to one embodiment of the present invention.

FIGS. 4A to 4D illustrate a method for manufacturing a semiconductor device according to one embodiment of the present invention.

FIGS. 5A and 5B illustrate a structure of a semiconductor device according to one embodiment of the present invention.

FIGS. 6A to 6D illustrate a method for manufacturing a semiconductor device according to one embodiment of the present invention.

FIGS. 7A to 7C illustrate a method for manufacturing a semiconductor device according to one embodiment of the present invention.

FIGS. 8A to 8D illustrate a method for manufacturing a semiconductor device according to one embodiment of the present invention.

FIGS. 9A to 9C illustrate a method for manufacturing a semiconductor device according to one embodiment of the present invention.

FIGS. 10A-1, 10A-2, and 10B are circuit diagrams of semiconductor devices according to one embodiment of the present invention.

FIGS. 11A and 11B are circuit diagrams of semiconductor devices according to one embodiment of the present invention.

FIGS. 12A to 12C are circuit diagrams of semiconductor devices according to one embodiment of the present invention.

FIGS. 13A to 13F each illustrate an electronic device using a semiconductor device according to one embodiment of the present invention.

FIG. 14 is an energy diagram of a reaction pathway according to one embodiment of the present invention and energy of respective states.

FIG. 15 is an energy diagram of a reaction pathway according to one embodiment of the present invention and energy of respective states.

FIG. 16 is a block diagram illustrating each component of a liquid crystal display device according to one embodiment of the present invention.

FIG. 17 illustrates a structure of a driver circuit and a pixel in a liquid crystal display device according to one embodiment of the present invention.

FIG. 18 is a timing chart showing an operation of a liquid crystal display device according to one embodiment of the present invention.

FIGS. 19A and 19B are timing charts showing operations of a display control circuit in a liquid crystal display device according to one embodiment of the present invention.

FIG. 20 schematically shows the frequency of writing image signals in frame periods in a period of displaying moving images and a period displaying still images according to one embodiment of the present invention.

### BEST MODE FOR CARRYING OUT THE INVENTION

Embodiments of the present invention are described in detail with reference to the accompanying drawings. Note that the present invention is not limited to the description below, and it is easily understood by those skilled in the art that modes and details disclosed herein can be modified in various ways without departing from the spirit and scope of the present invention. Therefore, the present invention should not be construed as being limited to the description in the following embodiments. Note that in the structures of the invention described below, the same portions or portions having similar functions are denoted by the same reference numerals in different drawings, and description of such portions is not repeated.

### Embodiment 1

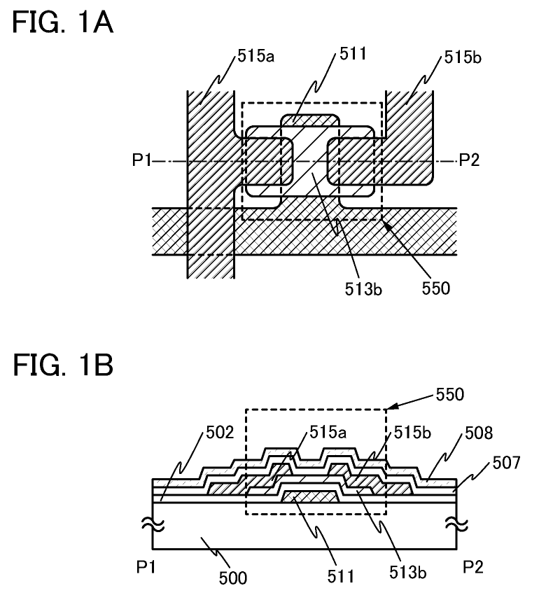

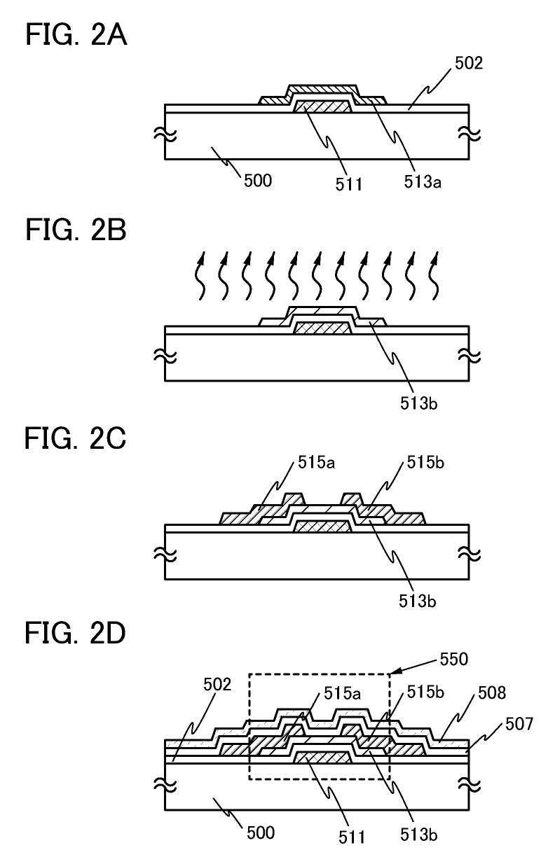

In this embodiment, a bottom-gate transistor which is manufactured by a method in which an oxide semiconductor layer is formed while a substance containing a halogen element is introduced into a film formation chamber in a gaseous state and is later subjected to heat treatment to form a highly purified oxide semiconductor layer, and a method for manufacturing the bottom-gate transistor will be described with reference to FIGS. 1A and 1B and FIGS. 2A to 2D.

FIGS. 1A and 1B illustrate a structure of a bottom-gate transistor 550 which is manufactured in this embodiment. FIG. 1A is a top view of the transistor 550, and FIG. 1B is a cross-sectional view of the transistor 550. Note that FIG. 1B corresponds to the cross-sectional view taken along a line P1-P2 in FIG. 1A.

In the transistor 550, a gate electrode 511 and a gate insulating layer 502 which covers the gate electrode 511 are provided over a substrate 500 having an insulating surface. A highly purified oxide semiconductor layer 513b which overlaps with the gate electrode 511 is provided over the gate insulating layer 502. In addition, a first electrode 515a and a second electrode 515b, which are in contact with the oxide semiconductor layer 513b, each serve as a source or drain electrode, and have end portions which overlaps with the gate electrode 511 are provided. Further, an insulating layer 507 which is in contact with the oxide semiconductor layer 513b and overlaps with a channel formation region thereof, and a protective insulating layer 508 which covers the transistor 550 are provided.

An oxide semiconductor used for a semiconductor layer in this embodiment is an i-type (intrinsic) or substantially i-type oxide semiconductor. The i-type (intrinsic) or substantially i-type oxide semiconductor is obtained in such a manner that hydrogen, which functions as an n-type impurity, is removed, and the oxide semiconductor is highly purified so as to contain as few impurities that are not main components of the oxide semiconductor as possible.

Note that the highly purified oxide semiconductor includes extremely few carriers, and the carrier concentration thereof is lower than 1×10¹⁴/cm³, preferably lower than 1×10¹²/cm³, or further preferably 1×10¹¹/cm³. Such few carriers enable current in an off state (off-state current) to be sufficiently low.

Specifically, in the transistor including the oxide semiconductor layer, the leakage current density (off-state current density) per micrometer of a channel width between the source and the drain in an off state can be less than or equal to 100 zA/μm (1×10⁻¹⁹ A/μm), preferably less than or equal to 10 zA/μm (1×10⁻²⁰ A/μm), or further preferably less than or equal to 1 zA/μm (1×10⁻²¹ A/μm) at a source-drain voltage of 3.5 V and a temperature when the transistor is in use (e.g., 25° C.).

In addition, in the transistor including the highly purified oxide semiconductor layer, the temperature dependence of off-state current is hardly observed, and off-state current remains extremely low even under a high temperature condition.

The oxide semiconductor layer 513b of the transistor 550 is formed in a film formation chamber into which a substance containing a halogen element is introduced in a gaseous state. In addition, in some cases, the oxide semiconductor layer 513b of the transistor 550 contains a halogen element. The concentration of the halogen element contained in the oxide semiconductor layer 513b is 10¹⁵ atoms/cm³ to 10¹⁸ atoms/cm³ inclusive. The halogen element in the oxide semiconductor layer 513b bonds to and terminates the dangling bond of a metal atom, which is generated during a manufacturing process of a semiconductor device; therefore, generation of carriers or an impurity level is suppressed.

Next, a method for manufacturing the transistor 550 over the substrate 500 will be described with reference to FIGS. 2A to 2D.

First, after a conductive film is formed over the substrate 500 having an insulating surface, a wiring layer including the gate electrode 511 is formed by a first photolithography step. Note that a resist mask may be formed by an ink-jet method. Formation of the resist mask by an ink-jet method needs no photomask; thus, manufacturing cost can be reduced.

In this embodiment, a glass substrate is used as the substrate 500 having an insulating surface.

An insulating film serving as a base film may be provided between the substrate 500 and the gate electrode 511. The base film has a function of preventing diffusion of an impurity element (e.g., an alkali metal such as Li or Na and an alkaline earth metal such as Ca) from the substrate 500, and can be formed to have a single-layer structure or a stacked-layer structure including one or more of a silicon nitride film, a silicon oxide film, a silicon nitride oxide film, and a silicon oxynitride film.

The gate electrode 511 can be formed to have a single-layer structure or a stacked-layer structure including a metal material such as molybdenum, titanium, tantalum, tungsten, neodymium, or scandium, or an alloy material which contains any of these metal materials as its main component.

Note that aluminum or copper can also be used as such a metal material if it can withstand the temperature of heat treatment to be performed in a later process. Aluminum or copper is preferably combined with a refractory metal material so as to prevent a heat resistance problem and a corrosive problem. As the refractory metal material, molybdenum, titanium, chromium, tantalum, tungsten, neodymium, scandium, or the like can be used.

In the case of using copper, a structure in which a Cu—Mg—Al alloy is provided for the layer serving as a base and copper is formed thereover is preferable. The provision of the Cu—Mg—Al alloy has an effect of enhancing adhesiveness between copper and the base such as an oxide film.

Next, the gate insulating layer 502 is formed over the gate electrode 511. The gate insulating layer 502 can be formed to have a single-layer structure or a stacked-layer structure including a silicon oxide layer, a silicon nitride layer, a silicon oxynitride layer, a silicon nitride oxide layer, an aluminum oxide layer, an aluminum nitride layer, an aluminum oxynitride layer, an aluminum nitride oxide layer, or a hafnium oxide layer by a plasma CVD method, a sputtering method, or the like.

As the oxide semiconductor of this embodiment, an i-type or substantially i-type oxide semiconductor is used. The i-type or substantially i-type oxide semiconductor is obtained in such a manner that film formation of an oxide semiconductor is performed while a substance containing a halogen element is introduced into the film formation chamber in a gaseous state and the oxide semiconductor is later subjected to heat treatment to remove impurities. Such a highly purified oxide semiconductor is extremely sensitive to an interface state density and interface charge; thus, an interface between the oxide semiconductor layer and the gate insulating layer is important. For that reason, the gate insulating layer in contact with a highly purified oxide semiconductor needs to have high quality.

For example, a high-density plasma CVD method using microwaves (e.g., a frequency of 2.45 GHz) is preferably employed because an insulating layer can be dense and can have high breakdown voltage and high quality. The highly purified oxide semiconductor and the high-quality gate insulating layer are in close contact with each other, whereby the interface state density can be reduced to obtain favorable interface characteristics.

Needless to say, another film formation method such as a sputtering method or a plasma CVD method can be employed as long as the method enables formation of a high-quality insulating layer as the gate insulating layer. Further, an insulating layer whose film quality and characteristic of the interface between the insulating layer and an oxide semiconductor are improved by heat treatment which is performed after formation of the insulating layer may be formed as the gate insulating layer. In any case, any insulating layer may be used as long as the insulating layer can reduce the interface state density of the interface between the insulating layer and an oxide semiconductor and form a favorable interface as well as having favorable film quality as the gate insulating layer.

Note that the gate insulating layer 502 is in contact with the oxide semiconductor layer to be formed later. When hydrogen diffuses in the oxide semiconductor layer, semiconductor characteristics deteriorate; therefore, it is preferable that the gate insulating layer 502 do not contain hydrogen, hydroxyl, and moisture. In order that the gate insulating layer 502 and an oxide semiconductor film contain as little hydrogen, hydroxyl, and moisture as possible, it is preferable that as pretreatment of film formation of the oxide semiconductor film, the substrate 500 over which the gate electrode 511 is formed or the substrate 500 over which layers up to the gate insulating layer 502 are formed be preheated in a preheating chamber of a sputtering apparatus, so that impurities such as hydrogen or moisture adsorbed onto the substrate 500 are eliminated and exhausted. As an exhaustion unit provided in the preheating chamber, a cryopump is preferable. Note that this preheating treatment can be omitted. Further, the above preheating may be performed in a similar manner on the substrate 500 in a state where the first electrode 515a and the second electrode 515b have been formed thereover but the insulating layer 507 has not been formed yet.

Next, an oxide semiconductor film having a thickness of 2 nm to 200 nm inclusive, preferably 5 nm to 30 nm inclusive is formed over the gate insulating layer 502.

The oxide semiconductor film is formed by a sputtering method using a metal oxide target. Moreover, the oxide semiconductor film can be formed by a sputtering method under a rare gas (e.g., argon) atmosphere, an oxygen atmosphere, or a mixed atmosphere containing a rare gas (e.g., argon) and oxygen.

Note that before the oxide semiconductor film is formed by a sputtering method, powdery substances (also referred to as particles or dust) which are attached on a surface of the gate insulating layer 502 are preferably removed by reverse sputtering in which an argon gas is introduced and plasma is generated. The reverse sputtering refers to a method in which, without application of a voltage to a target side, an RF power source is used for application of a voltage to a substrate side under an argon atmosphere to generate plasma in the vicinity of the substrate to modify a surface. Note that instead of an argon atmosphere, a nitrogen atmosphere, a helium atmosphere, an oxygen atmosphere, or the like may be used.

As an oxide semiconductor used for the oxide semiconductor film, the following metal oxide can be used: a four-component metal oxide such as an In—Sn—Ga—Zn—O based oxide semiconductor; a three-component metal oxide such as an In—Ga—Zn—O based oxide semiconductor, an In—Sn—Zn—O based oxide semiconductor, an In—Al—Zn—O based oxide semiconductor, a Sn—Ga—Zn—O based oxide semiconductor, an Al—Ga—Zn—O based oxide semiconductor, or a Sn—Al—Zn—O based oxide semiconductor; a two-component metal oxide such as an In—Zn—O based oxide semiconductor, a Sn—Zn—O based oxide semiconductor, an Al—Zn—O based oxide semiconductor, a Zn—Mg—O based oxide semiconductor, a Sn—Mg—O based oxide semiconductor, an In—Mg—O based oxide semiconductor, or an In—Ga—O based oxide semiconductor; an one-component metal oxide such as an In—O based oxide semiconductor, a Sn—O based oxide semiconductor, or a Zn—O based oxide semiconductor; or the like. Further, SiO₂ may be contained in the above oxide semiconductor. Addition of silicon oxide (SiOₓ (x>0)) which hinders crystallization to the oxide semiconductor film can suppress crystallization of the oxide semiconductor film at the time when heat treatment is performed after formation of the oxide semiconductor film in the manufacturing process. Here, for example, an In—Ga—Zn—O based oxide semiconductor means an oxide film containing indium (In), gallium (Ga), and zinc (Zn), and there is no particular limitation on the composition ratio thereof. The In—Ga—Zn—O based oxide semiconductor may contain an element other than In, Ga, and Zn.

For the oxide semiconductor film, a thin film represented by a chemical formula of InMO₃(ZnO)ₘ (m>0, and m is not a natural number) can be used. Here, M represents one or more metal elements selected from Ga, Al, Mn, and Co. For example, M can be Ga, Ga and Al, Ga and Mn, Ga and Co, or the like.

In the case where an In—Zn—O-based material is used as an oxide semiconductor, a target therefore has a composition ratio of In:Zn=50:1 to 1:2 in an atomic ratio (In₂O₃: ZnO=25:1 to 1:4 in a molar ratio), preferably, In:Zn=20:1 to 1:1 in an atomic ratio (In₂O₃: ZnO=10:1 to 1:2 in a molar ratio), further preferably, In:Zn=15:1 to 1.5:1 in an atomic ratio (In₂O₃: ZnO=15:2 to 3:4 in a molar ratio). For example, in a target used for formation of an In—Zn—O-based oxide semiconductor which has an atomic ratio of In:Zn:O=X:Y:Z, the relation of Z>1.5X+Y is satisfied.

The oxide semiconductor is preferably an oxide semiconductor containing In, further preferably an oxide semiconductor containing In and Ga. In order to obtain an I-type (intrinsic) oxide semiconductor, dehydration or dehydrogenation is effective. In this embodiment, the oxide semiconductor film is formed using an In—Ga—Zn—O based oxide target by a sputtering method.

As the target for forming the oxide semiconductor film by a sputtering method, for example, an oxide target containing In₂O₃, Ga₂O₃, and ZnO in a composition ratio of 1:1:1 [molar ratio] is used to form an In—Ga—Zn—O film. Without limitation to the material and the composition of the target, for example, a metal oxide target containing In₂O₃, Ga₂O₃, and ZnO in a composition ratio of 1:1:2 [molar ratio] or a metal oxide target containing In₂O₃, Ga₂O₃, and ZnO in a composition ratio of 1:1:4 [molar ratio] may be used.

The filling rate of the oxide target is 90% to 100% inclusive, preferably 95% to 99.9% inclusive. With the use of the metal oxide target with high filling rate, a dense oxide semiconductor film can be formed. Moreover, the purity of the target is preferably greater than or equal to 99.99%, where it is preferable that impurities, for example, an alkali metal such as Li or Na and an alkaline earth metal such as Ca be particularly reduced.

As a sputtering gas (including a substance containing a halogen element which is used in a gaseous state) used at the time of forming the oxide semiconductor film, a high-purity gas in which impurities such as hydrogen, water, hydroxyl, or hydride are removed is used. For example, it is preferable to use a high-purity gas in which such impurities are removed to the concentration of lower than or equal to 10 ppm, preferably lower than or equal to 1 ppm. Specifically, a high-purity gas in which a dew point is less than or equal to −60° C. is preferable.

As the substance containing a halogen element, which is introduced into the film formation chamber, a gas containing a fluorine atom (a fluorine-based gas such as tetrafluoride (CF₄), sulfur hexafluoride (SF₆), nitrogen trifluoride (NF₃), or trifluoromethane (CHF₃)), a gas containing a chlorine atom (a chlorine-based gas such as chlorine (Cl₂), boron trichloride (BCl₃), silicon tetrachloride (SiCl₄), or carbon tetrachloride (CCl₄)), or the like can be used as appropriate. It is particularly preferable to use the gas containing a fluorine atom because a fluorine radical is generated in plasma. The bond energy between a fluorine atom and a hydrogen atom is higher than the bond energy between any of the other halogen elements and a hydrogen atom. Further, this is because the bond between a fluorine atom and a hydrogen atom is more stable than the bond between any of the other halogen elements and a hydrogen atom.

Further, as a method for introducing a supply source of a halogen element into the film formation chamber, a method in which a gas containing a halogen element is added to a film formation gas is convenient and preferable. With the use of a gas containing a halogen element such as NF₃ described above for cleaning treatment on a treatment chamber for film formation, the oxide semiconductor film can be formed to contain a halogen element such as fluorine which is left remaining in the treatment chamber during the film formation.

The substrate is placed in the film formation chamber under reduced pressure, and the substrate temperature is set to a temperature of greater than or equal to 100° C. and less than or equal to 600° C., preferably greater than or equal to 200° C. and less than or equal to 400° C. By forming the oxide semiconductor film in a state where the substrate is heated, the concentration of impurities contained in the formed oxide semiconductor film can be reduced. In addition, damage by sputtering can be reduced. Then, a sputtering gas from which hydrogen and moisture are removed and to which the substance containing a halogen element is added in a gaseous state is introduced while residual moisture in the film formation chamber is removed using an exhaustion pump, and the oxide semiconductor film is formed over the substrate 500 using the above target. In order to remove the residual moisture in the film formation chamber and hydrogen and moisture that enter from the outside of the film formation chamber (hydrogen and moisture that enter due to leakage), an entrapment vacuum pump, for example, a cryopump, an ion pump, or a titanium sublimation pump is preferably used. The exhaustion unit may be a turbo pump provided with a cold trap. In the film formation chamber which is exhausted with the cryopump, for example, a hydrogen atom, and a compound containing a hydrogen atom, such as water (H₂O), (preferably, a compound containing a carbon atom) are removed, so that the concentration of impurities contained in the oxide semiconductor film formed in the film formation chamber can be reduced.

Note that the atmosphere under which sputtering is performed may be a rare gas (typically, argon) atmosphere to which the substance containing a halogen element is added in a gaseous state, an oxygen atmosphere to which the substance containing a halogen element is added in a gaseous state, or a mixed atmosphere containing a rare gas and oxygen to which the substance containing a halogen element is added in a gaseous state.

The substance containing a halogen element which is introduced into the film formation chamber is decomposed by plasma and generates a halogen radical. The generated halogen radical is reacted with the residual moisture in the film formation chamber and moisture that enters from the outside of the film formation chamber due to leakage, whereby a stable substance containing the hydrogen atom (hydrogen halide as an example) is generated. For example, when the oxide semiconductor film is formed under an atmosphere containing the substance containing a fluorine atom (NF₃ as an example), a fluorine radical reacts with moisture in the film formation chamber; thus, hydrogen fluoride is generated. Note that since the dissociation energy between a hydrogen atom and a fluorine atom in a hydrogen fluoride molecule is higher than the dissociation energy between a hydrogen atom and an oxygen atom in a water molecule, it can be said that a hydrogen fluoride molecule is more stable than a water molecule.

The moisture in the film formation chamber is exhausted from the film formation chamber after becoming hydrogen fluoride; therefore, the oxide semiconductor layer is hardly contaminated by moisture.

As an example of the film formation conditions, the distance between the substrate and the target is 100 mm, the pressure is 0.6 Pa, the direct-current (DC) power source is 0.5 kW, and the atmosphere is an oxygen atmosphere (the proportion of the oxygen flow rate is 100%). Note that a pulse-direct current power source is preferable because powder substances (also referred to as particles or dust) generated during the film formation can be reduced and the film thickness can be uniform.

Moreover, when the leakage rate of the treatment chamber of the sputtering apparatus is set to less than or equal to 1×10⁻¹⁰ Pa·m³/second, entry of impurities such as an alkali metal or hydride into the oxide semiconductor film under formation by a sputtering method can be reduced.

Further, with the use of an entrapment vacuum pump as an exhaustion system, counter flow of impurities such as an alkali metal, a hydrogen atom, a hydrogen molecule, water, hydroxyl, or hydride from the exhaustion system can be reduced.

Note that impurities, for example, an alkali metal such as Li or Na and an alkaline earth metal such as Ca contained in the oxide semiconductor layer are preferably reduced. Specifically, with the use of SIMS, the concentrations of the impurities such as Li, Na, and K contained in the oxide semiconductor layer are each lower than or equal to 5×10¹⁵ cm⁻³, preferably lower than or equal to 1×10¹⁵ cm⁻³.

An alkali metal and an alkaline earth metal are adverse impurities for an oxide semiconductor and are preferably contained little. When an insulating film in contact with the oxide semiconductor is an oxide, an alkali metal, in particular, Na diffuses in the oxide and becomes Na⁺. In addition, Na cuts the bond between a metal and oxygen or enters the bond in the oxide semiconductor. As a result, deterioration of transistor characteristics (e.g., the shift of a threshold value to the negative side (causing the transistor to be normally on) or a decrease in mobility) is caused. Additionally, this also causes variation in characteristics. Such a problem is significant especially in the case where the hydrogen concentration in the oxide semiconductor is sufficiently low). Therefore, the concentration of an alkali metal is strongly required to set in the above range in the case where the concentration of hydrogen contained in the oxide semiconductor is lower than or equal to 5×10¹⁹ cm⁻³, particularly lower than or equal to 5×10¹⁸ cm⁻³.

Next, the oxide semiconductor film is processed into an island-shaped oxide semiconductor layer 513a by a second photolithography step. A resist mask for forming the island-shaped oxide semiconductor layer may be formed by an ink-jet method. Formation of the resist mask by an ink-jet method needs no photomask; thus, manufacturing cost can be reduced.

In the case where a contact hole is formed in the gate insulating layer 502, a step of forming the contact hole can be performed at the same time as processing of the oxide semiconductor film.

Note that the etching of the oxide semiconductor film may be dry etching, wet etching, or both dry etching and wet etching. As an etchant used for wet etching for the oxide semiconductor film, for example, a mixed solution of phosphoric acid, acetic acid, and nitric acid, or the like can be used. In addition, ITO07N (produced by KANTO CHEMICAL CO., INC.) may also be used. Note that FIG. 2A is the cross-sectional view at this stage.

As an etching gas used for dry etching, a gas containing chlorine (a chlorine-based gas such as chlorine (Cl₂), boron trichloride (BCl₃), silicon tetrachloride (SiCl₄), or carbon tetrachloride (CCl₄)) is preferably used. Alternatively, a substance containing a fluorine atom (a fluorine-based gas such as carbon tetrafluoride (CF₄), sulfur hexafluoride (SF₆), nitrogen trifluoride (NF₃), or trifluoromethane (CHF₃)); hydrogen bromide (HBr); oxygen (O₂); any of these gases to which a rare gas such as helium (He) or argon (Ar) is added; or the like can be used.

As the dry etching method, a parallel plate RIE (reactive ion etching) method or an ICP (inductively coupled plasma) etching method can be used. In order to be able to etch the films into desired shapes, the etching condition (the amount of electric power applied to a coil-shaped electrode, the amount of electric power applied to an electrode on a substrate side, the temperature of the electrode on the substrate side, or the like) is adjusted as appropriate.

Next, first heat treatment is performed on the oxide semiconductor layer 513a. By this first heat treatment, impurities can be removed from the oxide semiconductor layer. For example, the hydrogen halide taken into the oxide semiconductor layer can be removed. The method in which produced hydrogen halide is removed by heating is easier than a method in which hydrogen or hydroxyl strongly bonded to the metal is directly removed.

The temperature of the first heat treatment is greater than or equal to 250° C. and less than or equal to 750° C., preferably greater than 400° C. and less than the strain point of the substrate. For example, heat treatment may be performed at 500° C. for approximately three minutes to six minutes inclusive. With an RTA (rapid thermal anneal) method for the heat treatment, dehydration or dehydrogenation can be performed in a short time; therefore, treatment can be performed even at a temperature higher than the strain point of a glass substrate. Whereas the substrates which are approximately as large as fourth-generation glass substrates can be subjected to heat treatment at a temperature in the range of greater than or equal to 250° C. and less than or equal to 750° C., the substrates which are approximately as large as sixth-generation to tenth-generation glass substrates is preferably subjected to heat treatment at a temperature in the range of greater than or equal to 250° C. and less than or equal to 450° C.

Here, the substrate is introduced into an electric furnace which is one of heat treatment apparatuses, heat treatment is performed on the oxide semiconductor layer at 600° C. under a nitrogen atmosphere, and then, slow cooling is performed on the oxide semiconductor layer to a temperature of less than or equal to 200° C. without exposure to the air so that entry of water and hydrogen into the oxide semiconductor layer is prevented. Thus, the oxide semiconductor layer 513b is obtained (see FIG. 2B). By performing slow cooling on the oxide semiconductor layer to a temperature of less than or equal to 200° C., the high-temperature oxide semiconductor layer can be prevented from being in contact with water or moisture in the air. When the high-temperature oxide semiconductor layer is in contact with water or moisture in the air, in some cases, the oxide semiconductor may be contaminated with an impurity containing a hydrogen atom.

Note that the heat treatment apparatus is not limited to the electric furnace, and an apparatus for heating an object by heat conduction or heat radiation from a heater such as a resistance heater may be used. For example, an RTA (rapid thermal anneal) apparatus such as a GRTA (gas rapid thermal anneal) apparatus or an LRTA (lamp rapid thermal anneal) apparatus can be used. An LRTA apparatus is an apparatus for heating an object by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas. As the high temperature gas, an inert gas which does not react with an object by heat treatment, such as nitrogen or a rare gas such as argon, is used.

For example, as the first heat treatment, GRTA by which the substrate is moved into an inert gas heated to a high temperature of 650° C. to 700° C., heated for several minutes, and moved out of the inert gas heated to the high temperature may be performed.

Note that in the first heat treatment, it is preferable that water, hydrogen, and the like be not contained in the atmosphere of nitrogen or a rare gas such as helium, neon, or argon. The purity of nitrogen or a rare gas such as helium, neon, or argon introduced into the heat treatment apparatus is preferably 5N (99.999%) or more, preferably 6N (99.9999%) or more (i.e., the impurity concentration is less than or equal to 10 ppm, preferably less than or equal to 1 ppm).

In addition, after the oxide semiconductor layer is heated by the first heat treatment, a high-purity oxygen gas, a high-purity N₂O gas, or ultra dry air (the moisture amount is less than or equal to 20 ppm (−55° C. by conversion into a dew point), preferably less than or equal to 1 ppm, or further preferably less than or equal to 10 ppb, in the case where measurement is performed with the use of a dew point meter of a cavity ring down laser spectroscopy (CRDS) system) may be introduced into the same furnace. It is preferable that the oxygen gas and the N₂O gas do not include water, hydrogen, and the like. The purity of the oxygen gas or the N₂O gas that is introduced into the heat treatment apparatus is preferably greater than or equal to 5N, further preferably greater than or equal to 6N (i.e., the concentration of impurities in the oxygen gas or the N₂O gas is preferably less than or equal to 10 ppm, further preferably less than or equal to 1 ppm). By the action of the oxygen gas or the N₂O gas, oxygen which is one of main components included in an oxide semiconductor and which has been reduced at the same time as the step for removing impurities by dehydration or dehydrogenation is supplied, so that the oxide semiconductor layer can be a highly purified and electrically i-type (intrinsic) oxide semiconductor.

In addition, the first heat treatment of the oxide semiconductor layer can also be performed on the oxide semiconductor film which has not yet been processed into the island-shaped oxide semiconductor layer. In that case, the substrate is taken out from the heat apparatus after the first heat treatment, and then a photolithography step is performed.

Note that the first heat treatment may be performed at any of the following timings in addition to the above timing as long as it is performed after the film formation of the oxide semiconductor film: after the source electrode and the drain electrode are stacked over the oxide semiconductor layer and after the insulating layer is formed over the source electrode and the drain electrode.

In the case where the contact hole is formed in the gate insulating layer 502, a step of forming the contact hole may be performed either before or after the first heat treatment is performed on the oxide semiconductor film.

Through the above steps, the concentration of hydrogen in the island-shaped oxide semiconductor layer can be reduced and the island-shaped oxide semiconductor layer can be highly purified. Accordingly, the oxide semiconductor layer can be stable. In addition, heat treatment at a temperature of less than or equal to the strain point of a glass substrate makes it possible to form an oxide semiconductor film with a wide band gap in which carrier density is extremely low. Therefore, a transistor can be manufactured using a large-sized substrate, so that productivity can be increased. In addition, by using the highly purified oxide semiconductor film in which the hydrogen concentration is reduced, it is possible to manufacture a transistor having high withstand voltage and extremely low off-state current. The above heat treatment can be performed at any time as long as it is performed after the oxide semiconductor layer 513a is formed.

Note that in the case where the oxide semiconductor film is heated, although depending on a material or heating conditions of the oxide semiconductor film, in some cases, plate-shaped crystals are formed at the surface of the oxide semiconductor film. The plate-like crystal is preferably a plate-like crystal which is c-axis-aligned in a direction substantially perpendicular to a surface of the oxide semiconductor film.

In addition, as the oxide semiconductor layer, an oxide semiconductor layer having a crystal region with a large thickness, that is, a crystal region which is c-axis-aligned perpendicularly to a surface of the film may be formed by performing film formation twice in the gas containing a halogen element and heat treatment twice, even when any of an oxide, a nitride, a metal, or the like is used for a material of a base component in contact with the oxide semiconductor layer 513a which is formed first. For example, after a first oxide semiconductor film having a thickness of 3 nm to 15 nm inclusive is formed, first heat treatment for crystallization is performed at a temperature of greater than or equal to 450° C. and less than or equal to 850° C., preferably greater than or equal to 550° C. and less than or equal to 750° C., under a nitrogen, oxygen, rare gas, or dry air atmosphere, whereby a first oxide semiconductor film having a crystal region (including a plate-like crystal) in a region including a surface is formed. Then, after a second oxide semiconductor film which has a larger thickness than the first oxide semiconductor film is formed in the gas containing a halogen element, second heat treatment for crystallization is performed at a temperature of greater than or equal to 450° C. and less than or equal to 850° C., preferably greater than or equal to 600° C. and less than or equal to 700° C., whereby crystal growth proceeds upward with the use of the first oxide semiconductor film as a seed of the crystal growth and the entire second oxide semiconductor film is crystallized. In such a manner, the oxide semiconductor layer having a crystal region having a large thickness can be formed. Note that the heat treatment for crystallization also serves as heat treatment for removing impurities (e.g., hydrogen halide) from the oxide semiconductor layer.

Moreover, an oxide semiconductor layer having a crystal region which is c-axis-aligned perpendicularly to a surface of the film may be formed by forming an oxide semiconductor layer while the substrate is heated to a temperature at which the oxide semiconductor is c-axis aligned. With such a film formation method, the number of steps can be reduced. The temperature for heating the substrate may be set as appropriate in accordance with other film formation conditions which differ depending on a film formation apparatus; for example, when the film formation is performed with a sputtering apparatus, the substrate temperature may be set to a temperature of greater than or equal to 250° C.

Next, a conductive film serving as a source electrode and a drain electrode (including a wiring formed in the same layer as the source electrode and the drain electrode) is formed over the gate insulating layer 502 and the oxide semiconductor layer 513b. As the conductive film used for the source electrode and the drain electrode, for example, a metal film containing an element selected from Al, Cr, Cu, Ta, Ti, Mo, and W or a metal nitride film containing any of the above elements as its component (a titanium nitride film, a molybdenum nitride film, or a tungsten nitride film) can be used. In the case of employing a metal film of Al, Cu, or the like, in order to prevent problems of heat resistance and corrosion, a metal film having a high melting point of Ti, Mo, W, Cr, Ta, Nd, Sc, Y, or the like or a metal nitride film of any of these elements (a titanium nitride film, a molybdenum nitride film, or a tungsten nitride film) may be stacked on one of or both a lower side and an upper side of the metal film.

Further, the conductive film can have a single-layer structure or a stacked-layer structure including two or more layers. For example, a single-layer structure of an aluminum film containing silicon; a two-layer structure of an aluminum film and a titanium film stacked thereover; a three-layer structure in which a titanium film, an aluminum film, and a titanium film are stacked in this order; and the like can be given.

Alternatively, the conductive film may be formed using conductive metal oxide. As the conductive metal oxide, indium oxide, tin oxide, zinc oxide, an alloy of indium oxide and tin oxide, an alloy of indium oxide and zinc oxide, or any of the metal oxide materials containing silicon or silicon oxide can be used.

Note that in the case where heat treatment is performed after the conductive film is formed, the conductive film preferably has heat resistance high enough to withstand the heat treatment.

Next, a resist mask is formed over the conductive film by a third photolithography step, the first electrode 515a and the second electrode 515b which each function as a source or drain electrode are formed by selective etching, and then the resist mask is removed (see FIG. 2C).

Light exposure at the time of forming the resist mask in the third photolithography step may be performed using ultraviolet light, KrF laser light, or ArF laser light. A channel length (L) of a transistor to be formed later is determined by a distance between bottom end portions of the first electrode and the second electrode, which are adjacent to each other over the oxide semiconductor layer 513b. In the case where light exposure is performed for a channel length (L) of less than 25 nm, the light exposure at the time of forming the resist mask in the third photolithography step may be performed using extreme ultraviolet light having an extremely short wavelength of several nanometers to several tens of nanometers. In the light exposure by extreme ultraviolet light, the resolution is high and the depth of focus is large. Therefore, the channel length (L) of the transistor to be formed later can be 10 nm to 1000 nm inclusive, whereby operation speed of a circuit can be increased.

In order to reduce the number of photomasks used in a photolithography step and reduce the number of photolithography steps, an etching step may be performed with the use of a resist mask formed using a multi-tone mask which is a light-exposure mask through which light is transmitted to have various intensities. A resist mask formed with the use of the multi-tone mask has a plurality of thicknesses and further can be changed in shape by etching; therefore, the resist mask can be used in a plurality of etching steps for processing into different patterns. Therefore, a resist mask corresponding to at least two kinds of different patterns can be formed by one multi-tone mask. Thus, the number of light-exposure masks can be reduced and the number of corresponding photolithography steps can be also reduced, whereby simplification of a process can be realized.

Note that it is preferable that etching conditions be optimized so as not to etch and divide the oxide semiconductor layer 513b when the conductive film is etched. However, it is difficult to obtain etching conditions in which only the conductive film is etched and the oxide semiconductor layer 513b is not etched at all. In some cases, when the conductive film is etched, only part of the oxide semiconductor layer 513b is etched to be an oxide semiconductor layer 513b having a groove portion (a recessed portion).

In this embodiment, a Ti film is used as the conductive film and the In—Ga—Zn—O based oxide semiconductor is used for the oxide semiconductor layer 513b; therefore, an ammonium hydrogen peroxide mixture (a mixed solution of ammonia, water, and hydrogen peroxide solution) is used as an etchant, so that the conductive film can be selectively etched.

Next, water or the like adsorbed to a surface of an exposed portion of the oxide semiconductor layer may be removed by plasma treatment using a gas such as N₂O, N₂, or Ar. Alternatively, plasma treatment may be performed using a mixed gas of oxygen and argon. In the case where the plasma treatment is performed, the insulating layer 507 serving as a protective insulating film in contact with part of the oxide semiconductor layer is formed without exposure to the air after the plasma treatment.

The insulating layer 507 preferably contains as little impurities such as moisture, hydrogen, and oxygen as possible, and may be formed using an insulating film of a single layer or a plurality of insulating films stacked.

The insulating layer 507 can be formed to a thickness of at least 1 nm by a method by which impurities such as water and hydrogen do not enter the insulating layer 507, such as a sputtering method, as appropriate. When hydrogen is contained in the insulating layer 507, entry of the hydrogen into the oxide semiconductor layer or extraction of oxygen in the oxide semiconductor layer by the hydrogen is caused, whereby a backchannel of the oxide semiconductor layer comes to be n-type (to have a lower resistance); thus, a parasitic channel might be formed. Therefore, it is important that a film formation method in which hydrogen is not used is employed in order to form the insulating layer 507 containing as little hydrogen atom as possible.

For example, an insulating film having a structure in which an aluminum oxide film having a thickness of 100 nm formed by a sputtering method is stacked over a gallium oxide film having a thickness of 200 nm formed by a sputtering method may be formed. The substrate temperature during the film formation may be in the range of greater than or equal to room temperature and less than or equal to 300° C. Further, the insulating film preferably contains much oxygen that exceeds the stoichiometric proportion, preferably at a proportion greater than 1 time and less than twice of the stoichiometric proportion. The insulating film contains excessive oxygen in such a manner, so that oxygen is supplied to the interface with the island-shaped oxide semiconductor film; thus, oxygen deficiency can be reduced.

In this embodiment, a silicon oxide film is formed to a thickness of 200 nm as the insulating layer 507 by a sputtering method. The substrate temperature during the film formation may be in the range of greater than or equal to room temperature and less than or equal to 300° C. and is set to 100° C. in this embodiment. The silicon oxide film can be formed by a sputtering method under a rare gas (typically, argon) atmosphere, an oxygen atmosphere, or a mixed atmosphere containing a rare gas and oxygen. As a target, a silicon oxide target or a silicon target can be used. For example, the silicon oxide film can be formed using a silicon target by a sputtering method under an atmosphere containing oxygen. As the insulating layer 507 which is formed in contact with the oxide semiconductor layer, an inorganic insulating film which does not include impurities such as moisture, a hydrogen ion, and OH⁻ and blocks entry of these from the outside is used. Typically, a silicon oxide film, a silicon oxynitride film, an aluminum oxide film, an aluminum oxynitride film, or the like is used.

In order to remove residual moisture in a film formation chamber of the insulating layer 507 at the same time as the film formation of the oxide semiconductor film, an entrapment vacuum pump (such as a cryopump) is preferably used. When the insulating layer 507 is formed in the film formation chamber exhausted using a cryopump, the concentration of an impurity contained in the insulating layer 507 can be reduced. In addition, as an exhaustion unit for removing the residual moisture in the film formation chamber of the insulating layer 507, a turbo pump provided with a cold trap may be used.

It is preferable that a high-purity gas in which impurities such as hydrogen, water, hydroxyl, or hydride are removed be used as the sputtering gas for the film formation of the insulating layer 507.

Note that after the insulating layer 507 is formed, second heat treatment (third heat treatment in the case where film formation and heat treatment of the oxide semiconductor layer are each performed twice) may be performed. The heat treatment is performed under an atmosphere of nitrogen, ultra-dry air, or a rare gas (argon, helium, or the like) preferably at a temperature of greater than or equal to 200° C. and less than or equal to 400° C., for example, greater than or equal to 250° C. and less than or equal to 350° C. It is preferable that the content of water in the gas be less than or equal to 20 ppm, preferably less than or equal to 1 ppm, or further preferably less than or equal to 10 ppb. Alternatively, RTA treatment may be performed at high temperature for a short time as in the first heat treatment. Even when oxygen deficiency is generated in the island-shaped oxide semiconductor layer by the first heat treatment, by performing heat treatment after the insulating layer 507 containing oxygen is provided, oxygen is supplied to the island-shaped oxide semiconductor layer from the insulating layer 507. Then, by supplying oxygen to the island-shaped oxide semiconductor layer, oxygen deficiency that serves as a donor is reduced in the island-shaped oxide semiconductor layer and the stoichiometric composition ratio can be satisfied. As a result, the island-shaped oxide semiconductor layer can be made to be substantially i-type and variation of electric characteristics of the transistor due to oxygen deficiency can be reduced, which result in improvement of the electric characteristics. The timing of this second heat treatment is not particularly limited as long as it is after the formation of the insulating layer 507, and this second heat treatment can be performed without increasing the number of steps by doubling as another step such as heat treatment for formation of a resin film or heat treatment for reduction of the resistance of a light-transmitting conductive film, so that the island-shaped oxide semiconductor layer can be made to be substantially i-type.

Moreover, the oxygen deficiency that serves as a donor in the island-shaped oxide semiconductor layer may be reduced by subjecting the island-shaped oxide semiconductor layer to heat treatment under an oxygen atmosphere so that oxygen is added to the oxide semiconductor. The heat treatment is performed at a temperature of, for example, greater than or equal to 100° C. and less than 350° C., preferably greater than or equal to 150° C. and less than 250° C. It is preferable that an oxygen gas used for the heat treatment under the oxygen atmosphere do not include water, hydrogen, or the like. Alternatively, the purity of the oxygen gas which is introduced into the heat treatment apparatus is preferably greater than or equal to 6N (99.9999%), preferably greater than or equal to 7N (99.99999%) (that is, the impurity concentration in the oxygen is less than or equal to 1 ppm, preferably less than or equal to 0.1 ppm).

In this embodiment, the second heat treatment (preferably at a temperature of greater than or equal to 200° C. and less than or equal to 400° C.) is performed under an inert gas atmosphere or an oxygen gas atmosphere. For example, the second heat treatment is performed at 250° C. under a nitrogen atmosphere for 1 hour. In the second heat treatment, heat is applied while part of the oxide semiconductor layer (the channel formation region) is in contact with the insulating layer 507.

The second heat treatment has the following effect. By the above first heat treatment, in some cases, whereas an impurity such as hydrogen, moisture, hydroxyl, or hydride (also referred to as a hydrogen compound) is intentionally removed from the oxide semiconductor layer, oxygen which is one of main components of the oxide semiconductor is reduced. Since the second heat treatment supplies oxygen to the oxide semiconductor layer subjected to the first heat treatment, the oxide semiconductor layer is highly purified to become an electrically i-type (intrinsic) semiconductor.

Through the above steps of forming the oxide semiconductor layer while a substance containing a halogen element is introduced into the film formation chamber in a gaseous state and then subjecting the oxide semiconductor layer to heat treatment, an impurity such as hydrogen, moisture, hydroxyl, or hydride (also referred to as a hydrogen compound) can be intentionally removed from the oxide semiconductor layer. Thus, the oxide semiconductor layer is highly purified to become electrically i-type (intrinsic) or substantially i-type. Through the above steps, the transistor 550 is formed.

When a silicon oxide layer having a lot of defects is used as the insulating layer 507, heat treatment after formation of the silicon oxide layer has an effect of diffusing an impurity such as hydrogen, moisture, hydroxyl, or hydride contained in the oxide semiconductor layer to the silicon oxide layer so that the impurity contained in the oxide semiconductor layer can be further reduced.

In the case where a silicon oxide layer including excessive oxygen is used as the insulating layer 507, heat treatment which is performed after the formation of the insulating layer 507 has an effect of moving oxygen in the insulating layer 507 to the oxide semiconductor layer 513b, and improving the oxygen concentration in the oxide semiconductor layer 513b and highly purifying the oxide semiconductor layer 513b.

The protective insulating layer 508 may be additionally formed over the insulating layer 507. The protective insulating layer 508 is formed by, for example, an RF sputtering method. Since an RF sputtering method has high mass productivity, it is preferably used as a film formation method of the protective insulating layer. As the protective insulating layer, an inorganic insulating film which does not contain impurities such as moisture and blocks the entry of the impurities from the outside is used; for example, a silicon nitride film or an aluminum nitride film is used. In this embodiment, the protective insulating layer 508 is formed using a silicon nitride film (see FIG. 2D).

In this embodiment, as the protective insulating layer 508, a silicon nitride film is formed by heating the substrate 500, over which layers up to the insulating layer 507 are formed, to a temperature of 100° C. to 400° C., introducing a sputtering gas containing high-purity nitrogen from which hydrogen and moisture are removed, and using a target of a silicon semiconductor. In this case also, it is preferable that residual moisture in the treatment chamber be removed in the formation of the protective insulating layer 508 in a manner similar to that of the insulating layer 507.

After the formation of the protective insulating layer, heat treatment may be further performed at a temperature of greater than or equal to 100° C. and less than or equal to 200° C. in the air for 1 hour to 30 hours inclusive. This heat treatment may be performed at a fixed heating temperature. Alternatively, the following change in the heating temperature may be conducted plural times repeatedly: the heating temperature is increased from room temperature to a temperature of greater than or equal to 100° C. and less than or equal to 200° C. and then decreased to room temperature.

In this embodiment, the method is described as an example, in which a substance containing a halogen element is introduced into a film formation chamber in a gaseous state during film formation, is reacted with an impurity containing a hydrogen atom which is left remaining in the film formation chamber, is changed to a stable substance containing the hydrogen atom, and is exhausted. With the method, the stable substance containing the hydrogen atom is exhausted without providing a metal atom of an oxide semiconductor layer with the hydrogen atom; therefore, a phenomenon in which a hydrogen atom or the like is taken into the oxide semiconductor layer can be prevented. As a result, a highly purified oxide semiconductor layer can be formed.

The transistor described as an example in this embodiment has a highly purified oxide semiconductor layer and small variation in a threshold voltage. Thus, a highly reliable semiconductor device can be provided by using the method for manufacturing a semiconductor device, which is described as an example in this embodiment. In addition, a semiconductor device with high mass productivity can be provided.

Further, a semiconductor device with low power consumption can be provided because off-state current can be reduced.

Note that since a transistor including an oxide semiconductor layer can obtain high field-effect mobility, high-speed driving is possible. Thus, when the transistor including an oxide semiconductor layer is used in a pixel portion in a liquid crystal display device, a high-quality image can be provided. In addition, by using the transistors including an oxide semiconductor layer, a driver circuit portion and a pixel portion are formed over one substrate; thus, the number of components of the liquid crystal display device can be reduced.

This embodiment mode can be combined as appropriate with any of the other embodiments described in this specification.

### Embodiment 2

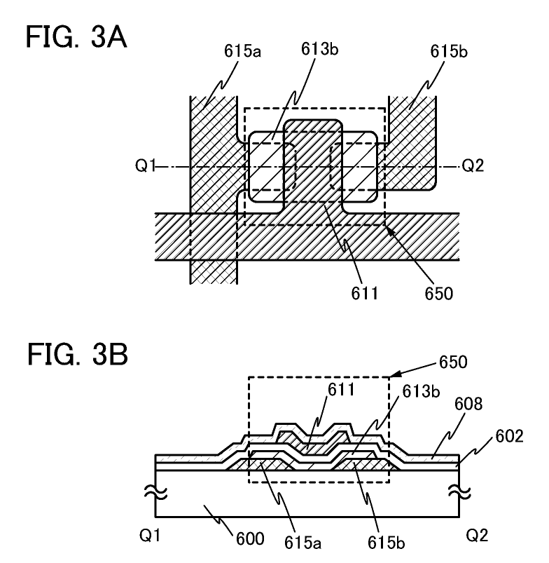

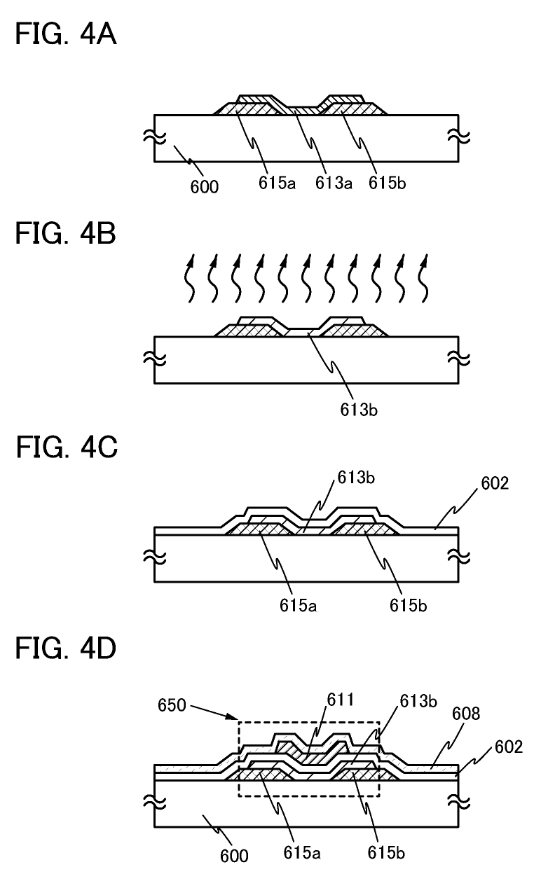

In this embodiment, a top-gate transistor which is manufactured by a method in which an oxide semiconductor layer is formed while a substance containing a halogen element is introduced into a film formation chamber in a gaseous state and is later subjected to heat treatment to form a highly purified oxide semiconductor layer, and a method for manufacturing the top-gate transistor will be described with reference to FIGS. 3A and 3B and FIGS. 4A to 4D.

FIGS. 3A and 3B illustrate a structure of a top-gate transistor 650 which is manufactured in this embodiment. FIG. 3A is a top view of the transistor 650, and FIG. 3B is a cross-sectional view of the transistor 650. Note that FIG. 3B corresponds to the cross-sectional view taken along a line Q1-Q2 in FIG. 3A.

In the transistor 650, over a substrate 600 having an insulating surface, a first electrode 615a and a second electrode 615b which each serve as a source or drain electrode are provided. A highly purified oxide semiconductor layer 613b which covers end portions of the first electrode 615a and the second electrode 615b, and a gate insulating layer 602 which covers the oxide semiconductor layer 613b are provided. In addition, a gate electrode 611 which is in contact with the gate insulating layer 602 and overlaps with the end portions of the first electrode 615a and the second electrode 615b, and a protective insulating layer 608 which is in contact with the gate electrode 611 and covers the transistor 650 are provided.

The oxide semiconductor layer 613b of the transistor 650 is formed in a film formation chamber into which a substance containing a halogen element is introduced in a gaseous state. In addition, in some cases, the oxide semiconductor layer 613b of the transistor 650 contains a halogen element. The concentration of the halogen element contained in the oxide semiconductor layer 613b is 10¹⁵ atoms/cm³ to 10¹⁸ atoms/cm³ inclusive. The halogen element in the oxide semiconductor layer 613b bonds to and terminates the dangling bond of a metal atom, which is generated during a manufacturing process of a semiconductor device; therefore, generation of carriers or an impurity level is suppressed.

Next, a method for manufacturing the transistor 650 over the substrate 600 will be described with reference to FIGS. 4A to 4D.

Next, a conductive film serving as a source electrode and a drain electrode (including a wiring formed in the same layer as the source electrode and the drain electrode) is formed over the substrate 600 having an insulating surface. As the conductive film used for the source electrode and the drain electrode, for example, a metal film containing an element selected from Al, Cr, Cu, Ta, Ti, Mo, and W or a metal nitride film containing any of the above elements as its component (a titanium nitride film, a molybdenum nitride film, or a tungsten nitride film) can be used. In the case of employing a metal film of Al, Cu, or the like, in order to prevent problems of heat resistance and corrosion, a metal film having a high melting point of Ti, Mo, W, Cr, Ta, Nd, Sc, Y, or the like or a metal nitride film of any of these elements (a titanium nitride film, a molybdenum nitride film, or a tungsten nitride film) may be stacked on one of or both a lower side and an upper side of the metal film. In particular, it is preferable to provide a conductive film containing titanium on the side in contact with the oxide semiconductor layer.

A resist mask is formed over the conductive film by a first photolithography step, the first electrode 615a and the second electrode 615b which each function as a source or drain electrode are formed by selective etching, and then the resist mask is removed. Note that a resist mask may be formed by an ink-jet method. Formation of the resist mask by an ink-jet method needs no photomask; thus, manufacturing cost can be reduced.

In this embodiment, a glass substrate is used as the substrate 600 having an insulating surface.

An insulating film serving as a base film may be provided between the substrate 600 and the first electrode 615a and the second electrode 615b. The base film has a function of preventing diffusion of an impurity element from the substrate 600, and can be formed to have a single-layer structure or a stacked-layer structure including one or more of a silicon nitride film, a silicon oxide film, a silicon nitride oxide film, and a silicon oxynitride film.

Then, an oxide semiconductor film having a thickness of 2 nm to 200 nm inclusive, preferably 5 nm to 30 nm inclusive is formed over the first electrode 615a and the second electrode 615b which each serve as a source or drain electrode.

Note that before the oxide semiconductor film is formed by a sputtering method, powdery substances (also referred to as particles or dust) which are attached on surfaces of the first electrode 615a and the second electrode 615b, and the insulating surface of the exposed portion of the substrate 600 are preferably removed by reverse sputtering in which an argon gas is introduced and plasma is generated. The reverse sputtering refers to a method in which an RF power source is used for application of a voltage to a substrate side under an argon atmosphere to generate plasma in the vicinity of the substrate to modify a surface. Note that instead of an argon atmosphere, a nitrogen atmosphere, a helium atmosphere, an oxygen atmosphere, or the like may be used.

The oxide semiconductor film described in this embodiment can be formed using a material, a method, and conditions similar to those of the oxide semiconductor film described in Embodiment 1. Specifically, an oxide semiconductor used for the oxide semiconductor film, a film formation method, a target composition, a target filling rate, the purity of a sputtering gas, a halogen gas introduced into a film formation chamber, substrate temperature during the film formation, an exhaustion unit of a sputtering apparatus, a composition of the sputtering gas, and the like may be similar to those in Embodiment 1. Therefore, Embodiment 1 can be referred to for the details.

Next, the oxide semiconductor film is processed into an island-shaped oxide semiconductor layer 613a by a second photolithography step. A resist mask for forming the island-shaped oxide semiconductor layer may be formed by an ink-jet method. Formation of the resist mask by an ink-jet method needs no photomask; thus, manufacturing cost can be reduced.

Note that the etching of the oxide semiconductor film may be dry etching, wet etching, or both dry etching and wet etching. As an etchant used for wet etching for the oxide semiconductor film, for example, a mixed solution of phosphoric acid, acetic acid, and nitric acid, or the like can be used. In addition, ITO07N (produced by KANTO CHEMICAL CO., INC.) may also be used. Note that FIG. 4A is the cross-sectional view at this stage.

Next, first heat treatment is performed on the oxide semiconductor layer 613a. By this first heat treatment, impurities can be removed from the oxide semiconductor layer. For example, the hydrogen halide taken into the oxide semiconductor layer can be removed. The method in which produced hydrogen halide is removed by heating is easier than a method in which hydrogen or hydroxyl strongly bonded to the metal is directly removed.

The temperature of the first heat treatment is greater than or equal to 250° C. and less than or equal to 700° C., preferably greater than or equal to 250° C. and less than or equal to 450° C. or greater than 250° C. and less than the strain point of the substrate. Whereas the substrates which are approximately as large as fourth-generation glass substrates can be subjected to heat treatment at a temperature in the range of greater than or equal to 250° C. and less than or equal to 700° C., the substrates which are approximately as large as about sixth-generation to tenth-generation glass substrates is preferably subjected to heat treatment at a temperature in the range of greater than or equal to 250° C. and less than or equal to 450° C.

Here, the substrate is introduced into an electric furnace which is one of heat treatment apparatuses, heat treatment is performed on the oxide semiconductor layer at 600° C. under a nitrogen atmosphere, and then, slow cooling is performed on the oxide semiconductor layer to a temperature of less than or equal to 200° C. without exposure to the air so that entry of water and hydrogen into the oxide semiconductor layer is prevented. Thus, the oxide semiconductor layer 613b is obtained (see FIG. 4B). By performing slow cooling on the oxide semiconductor layer to a temperature of less than or equal to 200° C., the high-temperature oxide semiconductor layer can be prevented from being in contact with water or moisture in the air. When the high-temperature oxide semiconductor layer is in contact with water or moisture in the air, in some cases, the oxide semiconductor is contaminated with an impurity containing a hydrogen atom.

Note that the heat treatment apparatus is not limited to an electric furnace, and a heating unit, a heating method, and heating conditions described in Embodiment 1 can be used. Specifically, a heat treatment apparatus, heating temperature, and the kind, the purity, and the like of a gas used for heating may be similar to those in Embodiment 1. Therefore, Embodiment 1 can be referred to for the details.

In addition, the first heat treatment can also be performed on the oxide semiconductor film which has not yet been processed into the island-shaped oxide semiconductor layer. In that case, the substrate is taken out from the heat apparatus after the first heat treatment, and then a photolithography step is performed.

Note that the first heat treatment may be performed at any of the following timings in addition to the above timing as long as it is performed after the film formation of the oxide semiconductor film: after the gate insulating layer is stacked over the oxide semiconductor layer and after the gate electrode is formed over the gate insulating layer.

In addition, as the oxide semiconductor layer, an oxide semiconductor layer having a crystal region with a large thickness, that is, a crystal region which is c-axis-aligned perpendicularly to a surface of the film may be formed by performing film formation twice and heat treatment twice in the gas containing a halogen element, even when any of an oxide, a nitride, a metal, or the like is used for a material of a base component in contact with the oxide semiconductor layer 613a which is formed first. Note that the film formation conditions described in Embodiment 1 can be used for forming the oxide semiconductor layer including a crystal region. Therefore, Embodiment 1 can be referred to for the details.

Next, water or the like adsorbed to a surface of an exposed portion of the oxide semiconductor layer may be removed by plasma treatment using a gas such as N₂O, N₂, or Ar. In the case where the plasma treatment is performed, the gate insulating layer 602 in contact with the oxide semiconductor layer is formed without exposure to the air after the plasma treatment.

As the oxide semiconductor of this embodiment, an i-type or substantially i-type oxide semiconductor is used from which impurities are removed. Such a highly purified oxide semiconductor is extremely sensitive to an interface state density and interface charge; thus, an interface between the oxide semiconductor layer and the gate insulating layer is important. For that reason, the gate insulating layer in contact with a highly purified oxide semiconductor needs to have high quality.

The gate insulating layer 602 can be formed to a thickness of at least 1 nm by a method by which impurities such as water and hydrogen do not enter the gate insulating layer 602, such as a sputtering method, as appropriate. When hydrogen is contained in the gate insulating layer 602, entry of the hydrogen into the oxide semiconductor layer or extraction of oxygen in the oxide semiconductor layer by the hydrogen is caused, whereby a channel of the oxide semiconductor layer comes to be n-type (to have a lower resistance); thus, a parasitic channel might be formed. Therefore, it is important that a film formation method in which hydrogen is not used is employed in order to form the gate insulating layer 602 containing as little hydrogen atom as possible.

In this embodiment, a silicon oxide film is formed as the gate insulating layer 602 by a sputtering method. The substrate temperature during the film formation may be in the range of greater than or equal to room temperature and less than or equal to 300° C. and is set to 100° C. in this embodiment. The silicon oxide film can be formed by a sputtering method under a rare gas (typically, argon) atmosphere, an oxygen atmosphere, or a mixed atmosphere containing a rare gas and oxygen. As a target, a silicon oxide target or a silicon target can be used. For example, the silicon oxide film can be formed using a silicon target by a sputtering method under an atmosphere containing oxygen. As the gate insulating layer 602 which is formed in contact with the oxide semiconductor layer, an inorganic insulating film which does not include impurities such as moisture, a hydrogen ion, and OH⁻ and blocks entry of these from the outside is used. Typically, a silicon oxide film, a silicon oxynitride film, an aluminum oxide film, an aluminum oxynitride film, or the like is used.

In order to remove residual moisture in the film formation chamber of the gate insulating layer 602 at the same time as the film formation of the oxide semiconductor film, an entrapment vacuum pump (such as a cryopump) is preferably used. When the gate insulating layer 602 is formed in the film formation chamber exhausted using a cryopump, the concentration of an impurity contained in the gate insulating layer 602 can be reduced. In addition, as an exhaustion unit for removing the residual moisture in the film formation chamber of the gate insulating layer 602, a turbo pump provided with a cold trap may be used.

It is preferable that a high-purity gas in which impurities such as hydrogen, water, hydroxyl, or hydride are removed be used as the sputtering gas for the film formation of the gate insulating layer 602. Note that FIG. 4C is the cross-sectional view at this stage.

When a contact hole is formed in the gate insulating layer 602, the contact hole is formed in the gate insulating layer 602 by a third photolithography step. Note that the contact hole is not illustrated in FIG. 4D.

Next, after a conductive film is formed over the gate insulating layer 602, a wiring layer including the gate electrode 611 is formed by a fourth photolithography step. Note that a resist mask may be formed by an ink-jet method. Formation of the resist mask by an ink-jet method needs no photomask; thus, manufacturing cost can be reduced.

The gate electrode 611 can be formed to have a single-layer structure or a stacked-layer structure including a metal material such as molybdenum, titanium, tantalum, tungsten, aluminum, copper, neodymium, or scandium, or an alloy material which contains any of these metal materials as its main component.

The protective insulating layer 608 may be formed over the gate electrode 611. The protective insulating layer 608 is formed by, for example, an RF sputtering method. Since an RF sputtering method has high mass productivity, it is preferably used as a film formation method of the protective insulating layer. As the protective insulating layer, an inorganic insulating film which does not contain impurities such as moisture and blocks the entry of the impurities from the outside is used; for example, a silicon nitride film or an aluminum nitride film is used. In this embodiment, the protective insulating layer 608 is formed using a silicon nitride film. Note that FIG. 4D is the cross-sectional view at this stage.

In this embodiment, as the protective insulating layer 608, a silicon nitride film is formed by heating the substrate 600, over which layers up to the gate electrode 611 are formed, to a temperature of 100° C. to 400° C., introducing a sputtering gas containing high-purity nitrogen from which hydrogen and moisture are removed, and using a target of a silicon semiconductor. In this case also, it is preferable that residual moisture in the treatment chamber be removed in the formation of the protective insulating layer 608 in a manner similar to that of the gate insulating layer 602.

After the formation of the protective insulating layer, heat treatment may be further performed at a temperature of greater than or equal to 100° C. and less than or equal to 200° C. in the air for 1 hour to 30 hours inclusive. This heat treatment may be performed at a fixed heating temperature. Alternatively, the following change in the heating temperature may be conducted plural times repeatedly: the heating temperature is increased from room temperature to a temperature of greater than or equal to 100° C. and less than or equal to 200° C. and then decreased to room temperature.

In this embodiment, the method is described as an example, in which a substance containing a halogen element is introduced into a film formation chamber in a gaseous state during film formation, is reacted with an impurity containing a hydrogen atom which is left remaining in the film formation chamber, is changed to a stable substance containing the hydrogen atom, and is exhausted. With the method, the stable substance containing the hydrogen atom is exhausted without providing a metal atom of an oxide semiconductor layer with the hydrogen atom; therefore, a phenomenon in which a hydrogen atom or the like is taken into the oxide semiconductor layer can be prevented. As a result, a highly purified oxide semiconductor layer can be formed.

The transistor described as an example in this embodiment has a highly purified oxide semiconductor layer and small variation in a threshold voltage. Thus, a highly reliable semiconductor device can be provided by using the method for manufacturing a semiconductor device, which is described as an example in this embodiment. In addition, a semiconductor device with high mass productivity can be provided.

Further, a semiconductor device with low power consumption can be provided because off-state current can be reduced.

Note that since a transistor including an oxide semiconductor layer can obtain high field-effect mobility, high-speed driving is possible. Thus, when the transistor including an oxide semiconductor layer is used in a pixel portion in a liquid crystal display device, a high-quality image can be provided. In addition, by using the transistors including an oxide semiconductor layer, a driver circuit portion and a pixel portion are formed over one substrate; thus, the number of components of the liquid crystal display device can be reduced.

This embodiment mode can be combined as appropriate with any of the other embodiments described in this specification.

### Embodiment 3

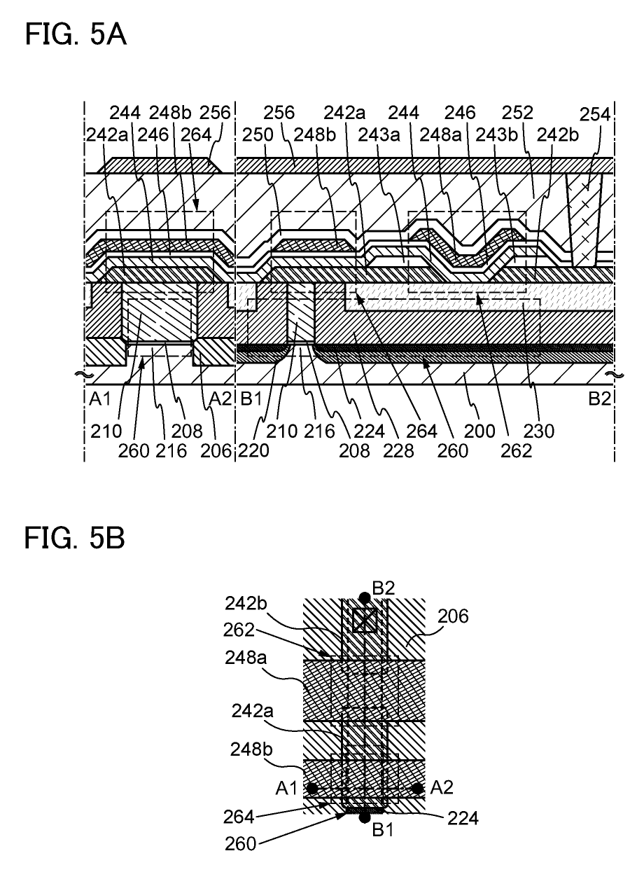

In this embodiment, a structure and a method for manufacturing a semiconductor device according to one embodiment of the present invention will be described with reference to FIGS. 5A and 5B, FIGS. 6A to 6D, FIGS. 7A to 7C, FIGS. 8A to 8D, and FIGS. 9A to 9C. Note that the semiconductor device described as an example in this embodiment can be used as a memory device.

A structure of a semiconductor device described as an example in this embodiment is illustrated in FIGS. 5A and 5B. FIG. 5A is a cross-sectional view of the semiconductor device, and FIG. 5B is a plan view of the semiconductor device. Note that FIG. 5A is a cross-sectional view taken along line A1-A2 and line B1-B2 in FIG. 5B.

The semiconductor device described as an example includes a transistor 260 including a first semiconductor material in a lower portion, a transistor 262 including a second semiconductor material in an upper portion, and a capacitor 264. A gate electrode 210 of the transistor 260 is directly connected to a first electrode 242a of the transistor 262.

In the case where the transistor 262 and the capacitor 264 are provided so as to overlap with the transistor 260, high integration can be achieved. For example, given that the minimum feature size is F, the area occupied by a memory cell can be 15F² to 25F² by devising the connection between a wiring and an electrode.

The first semiconductor material included in the transistor 260 and the second semiconductor material included in the transistor 262 can be different. For example, a single crystal semiconductor may be used as the first semiconductor material so that the transistor 260 can be driven at high speed, and an oxide semiconductor may be used as the second semiconductor material so that the off-state current of the transistor 262 can be sufficiently reduced and charge can be held for a long time.

As the first semiconductor material and the second semiconductor material, an oxide semiconductor or a semiconductor material other than the oxide semiconductor may be used, for example. As the semiconductor material other than the oxide semiconductor, silicon, germanium, silicon germanium, silicon carbide, gallium arsenide, or the like can be used. Alternatively, an organic semiconductor material or the like can be used.

In this embodiment, the case where single crystal silicon is used as the first semiconductor material so that the transistor 260 can be driven at high speed and an oxide semiconductor is used as the second semiconductor material so that the transistor 262 whose off-state current is reduced is formed will be described.

A semiconductor device having such a structure that the gate electrode 210 of the transistor 260 is connected to the first electrode 242a of the transistor 262 is favorable as a memory device. When the transistor 262 is in an off state, the potential of the gate electrode 210 of the transistor 260 can be held for an extremely long time. When the capacitor 264 is provided, charge supplied to the gate electrode 210 of the transistor 260 can be held easily and reading of the held data can be performed easily. In addition, with the transistor 260 including such a semiconductor material capable of operating at high speed, data can be read at high speed.

Although all the transistors included in the semiconductor device described as an example in this embodiment are n-channel transistors here, it is needless to say that p-channel transistors can be used. The technical nature of the invention disclosed herein is that a transistor including an oxide semiconductor whose off-state current is sufficiently reduced and a transistor including a semiconductor material other than an oxide semiconductor which is capable of sufficiently-high-speed driving are provided in combination. Accordingly, it is not necessary to limit specific conditions, such as a material used for the semiconductor device or a structure of the semiconductor device, to the conditions described here.

The transistor 260 includes a channel formation region 216 provided in a substrate 200 including the first semiconductor material and impurity regions 220 which sandwich the channel formation region 216 therebetween. Further, the transistor 260 includes metal compound regions 224 which are in contact with the impurity regions 220, a gate insulating layer 208 provided over the channel formation region 216, and the gate electrode 210 provided over the gate insulating layer 208. Note that in some cases, a transistor whose source and drain electrodes are not explicitly illustrated in the drawing may be referred to as a transistor for the sake of convenience. Further, in this case, in description of the connection between transistors, a source region and a drain region may be referred to as a source electrode and a drain electrode, respectively, in some cases. In other words, in this specification, the term “source electrode” may include a source region and the term “drain electrode” may include a drain region.

Further, an element isolation insulating layer 206 is provided over the substrate 200 so as to surround the transistor 260, and an insulating layer 228 and an insulating layer 230 are provided over the transistor 260. Although not illustrated, part of the metal compound regions 224 of the transistor 260 is connected to a wiring 256 or another wiring via an electrode which functions as a source or drain electrode. Note that in some cases, a transistor whose source and drain electrodes are not explicitly illustrated in the drawing may be referred to as a transistor for the sake of convenience.

In order to obtain high integration, the transistor 260 preferably does not have a sidewall insulating layer as illustrated in FIGS. 5A and 5B. On the other hand, in the case where characteristics of the transistor 260 are emphasized, a sidewall insulating layer may be provided on a side surface of the gate electrode 210, and the impurity regions 220 may include an impurity region which has a different impurity concentration from the impurity regions 220 and is provided in a region which overlaps with the sidewall insulating layer.

In this embodiment, a single crystal silicon substrate is used as the substrate 200 including the first semiconductor material. In the case of using a single crystal semiconductor substrate of silicon or the like, the reading operation of the semiconductor device can be performed at higher speed.

The transistor 262 includes a highly purified oxide semiconductor layer as the second semiconductor material. The transistor 262 includes the first electrode 242a and a second electrode 242b which function as a source electrode and a drain electrode over the insulating layer 230, and an oxide semiconductor layer 244 electrically connected to the first electrode and the second electrode. Further, the transistor 262 includes a gate insulating layer 246 which covers the oxide semiconductor layer 244 and a gate electrode 248a which is positioned over the gate insulating layer 246 and overlaps with the oxide semiconductor layer 244. In addition, an insulating layer 243a is provided between the first electrode 242a and the oxide semiconductor layer 244 so as to overlap with the gate electrode 248a, and an insulating layer 243b is provided between the second electrode 242b and the oxide semiconductor layer 244 so as to overlap with the gate electrode 248a.

The insulating layer 243a and the insulating layer 243b reduce capacitance generated between the gate electrode and the source or drain electrode. However, a structure without the insulating layer 243a and the insulating layer 243b may also be employed.

Here, the oxide semiconductor layer 244 is preferably an oxide semiconductor layer which is highly purified by sufficiently removing an impurity such as hydrogen therefrom and supplying a sufficient amount of oxygen thereto. Specifically, the concentration of hydrogen in the oxide semiconductor layer 244 is lower than or equal to 5×10¹⁹ atoms/cm³, preferably lower than or equal to 5×10¹⁸ atoms/cm³, or further preferably lower than or equal to 5×10¹⁷ atoms/cm³, for example. Note that the above concentration of hydrogen in the oxide semiconductor layer 244 is measured by secondary ion mass spectroscopy (SIMS). In the oxide semiconductor layer 244 which is highly purified by sufficiently reducing the concentration of hydrogen and in which defect levels in an energy gap due to oxygen deficiency are reduced by supplying a sufficient amount of oxygen, the carrier concentration resulted from hydrogen, an oxygen deficiency, or the like is less than 1×10¹²/cm³, preferably less than 1×10¹¹/cm³, or further preferably less than 1.45×10¹⁰/cm³.

The off-state current can be sufficiently reduced in the transistor including the oxide semiconductor layer 244. For example, in a transistor in which the oxide semiconductor layer 244 has a thickness of 30 nm and a channel length of 2 μm, the off-state current (a gate bias: −3 V) per channel length of 1 μm at room temperature (25° C.) is less than or equal to 100 zA (1 zA (zeptoampere) is equal to 1×10⁻²¹ A), preferably less than or equal to 10 zA.

In this embodiment, the highly purified oxide semiconductor layer is formed by employing such a method in which, after an oxide semiconductor layer is formed while a substance containing a halogen element is introduced into a film formation chamber in a gaseous state, the oxide semiconductor layer is subjected to heat treatment. By using a highly purified oxide semiconductor in such a manner, the transistor 262 with excellent off-state current characteristics can be obtained. Embodiment 2 can be referred to for the details of the structure and the manufacturing method of the oxide semiconductor layer 244.

Although the oxide semiconductor layer 244 which is processed to have an island shape is used in the transistor 262 of FIGS. 5A and 5B in order to suppress leakage current between elements due to miniaturization, a structure including the oxide semiconductor layer 244 which is not processed to have an island shape may be employed. In the case where the oxide semiconductor layer is not processed to have an island shape, contamination of the oxide semiconductor layer 244 due to etching in processing can be prevented.

In the semiconductor device illustrated in FIGS. 5A and 5B as an example, a top surface of the gate electrode 210 of the transistor 260 is not covered by the insulating layer 230 and is directly connected to the first electrode 242a which functions as a source or drain electrode of the transistor 262. The gate electrode 210 can be connected to the first electrode 242a through an opening and an electrode which are additionally provided for the contact. However, in the case of direct connection, the contact area can be reduced and high integration of the semiconductor device can be achieved.

For example, in the case where the semiconductor device of this embodiment is used as a memory device, high integration is crucial for an increase of storage capacity per unit area. In addition, a step necessary for forming an opening and an electrode which are additionally formed for the contact can be omitted; therefore, a process for manufacturing a semiconductor device can be simplified.

The capacitor 264 in FIGS. 5A and 5B includes the first electrode 242a which functions as the source or drain electrode, the oxide semiconductor layer 244, the gate insulating layer 246, and an electrode 248b. That is, the first electrode 242a functions as one of electrodes of the capacitor 264, and the electrode 248b functions as the other of the electrodes of the capacitor 264.

In the capacitor 264 illustrated in FIGS. 5A and 5B as an example, the oxide semiconductor layer 244 and the gate insulating layer 246 are sandwiched between the first electrode 242a and the electrode 248b; however, only the gate insulating layer 246 may be sandwiched for larger capacity. Further, the capacitor 264 may have a structure including an insulating layer formed in a manner similar to that of the insulating layer 243a. In the case where a capacitor is not needed, it is possible to employ a structure without the capacitor 264.

Further, an insulating layer 250 is provided over the transistor 262 and the capacitor 264, and an insulating layer 252 is provided over the insulating layer 250. In an opening formed in the gate insulating layer 246, the insulating layer 250, the insulating layer 252, and the like, an electrode 254 is provided. The wiring 256 is provided over the insulating layer 252 and is electrically connected to the second electrode 242b through the electrode 254. Note that the wiring 256 may be configured to be in direct contact with the second electrode 242b.

In addition, an electrode (not illustrated) connected to the metal compound region 224 may be connected to the second electrode 242b. In this case, when the electrode 254 and the electrode connected to the metal compound region 224 are disposed so as to overlap with each other, high integration of the semiconductor device can be achieved.

### <Method for Manufacturing Semiconductor Device>

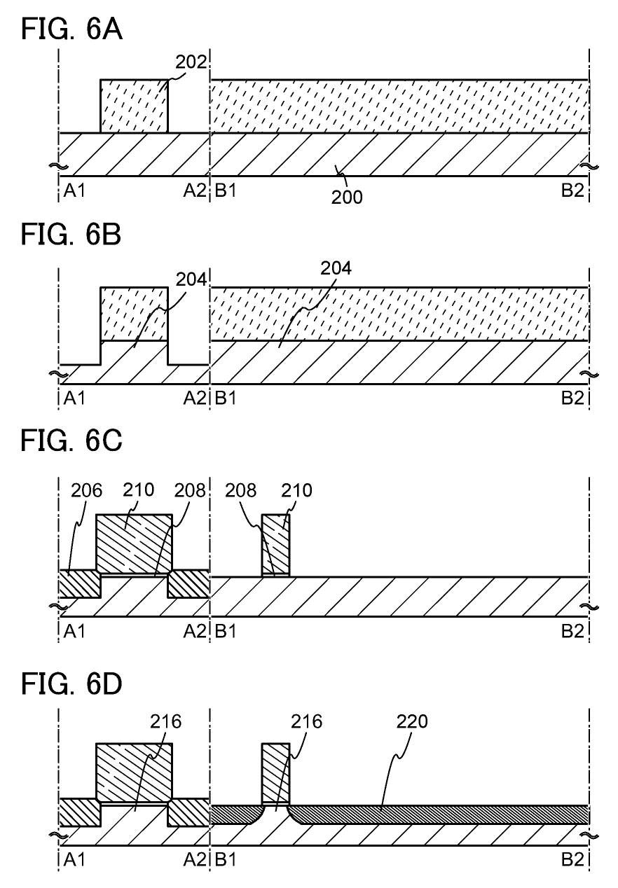

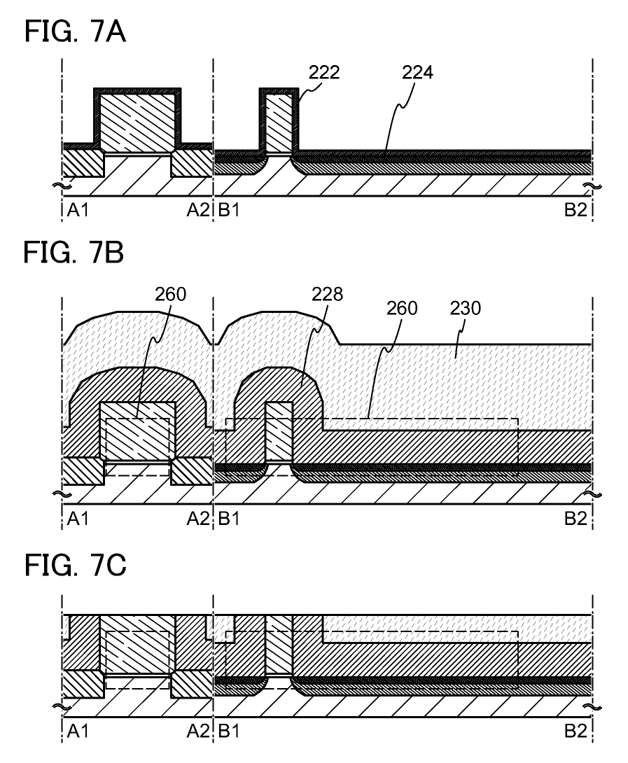

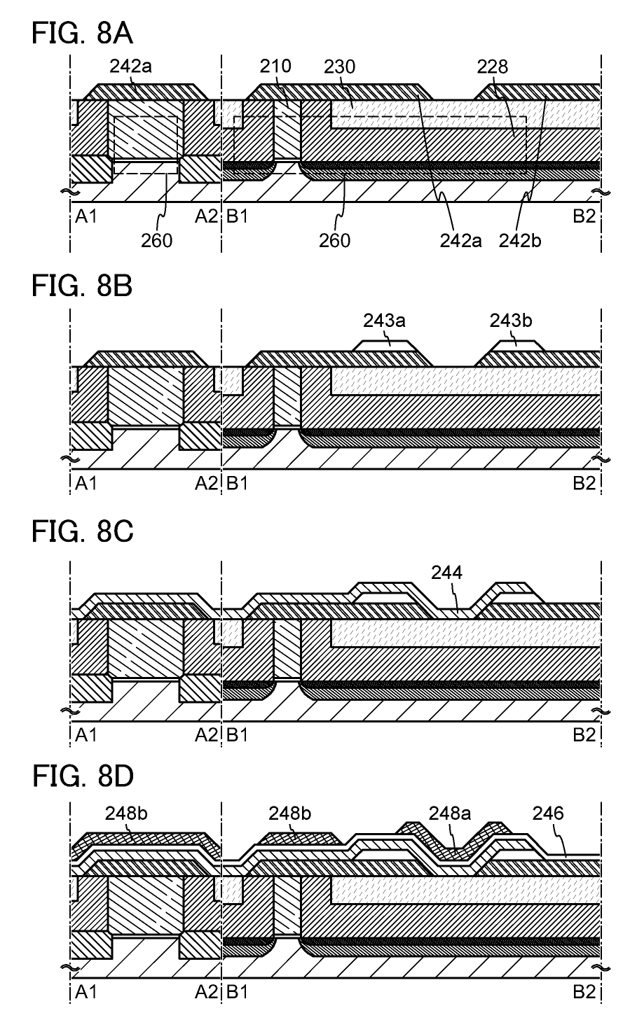

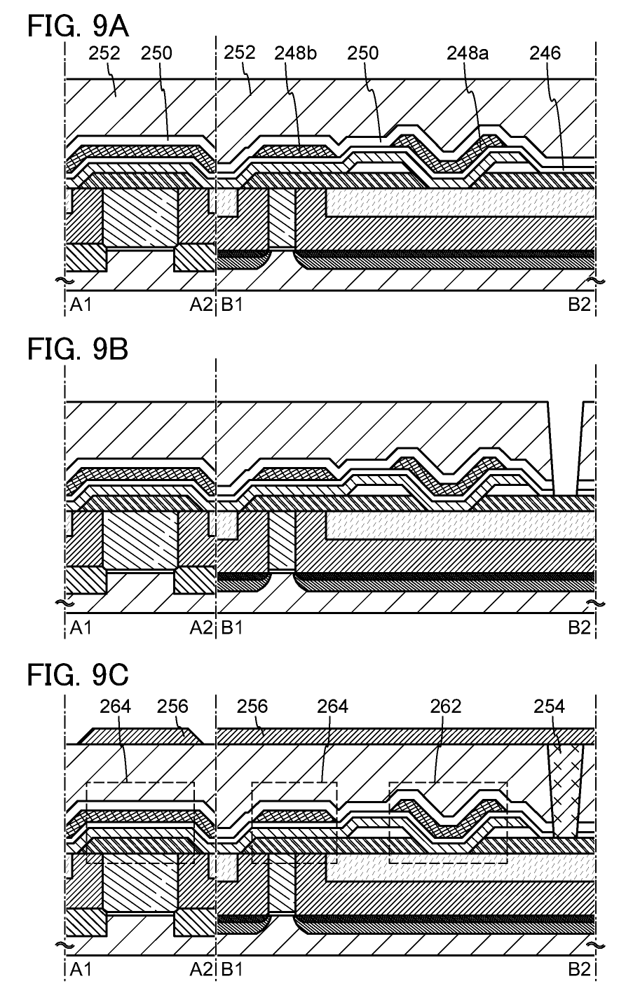

Next, an example of a method for manufacturing the semiconductor device will be described. First, a method for manufacturing the lower transistor 260 will be described below with reference to FIGS. 6A to 6D and FIGS. 7A to 7C, and then a method for manufacturing the upper transistor 262 and the capacitor 264 will be described with reference to FIGS. 8A to 8D and FIGS. 9A to 9C.

### <Method for Manufacturing Lower Transistor>

First, the substrate 200 including a semiconductor material is prepared (see FIG. 6A). As the substrate 200 including a semiconductor material, a single crystal semiconductor substrate or a polycrystalline semiconductor substrate of silicon, silicon carbide, or the like; a compound semiconductor substrate of silicon germanium or the like; an SOI substrate; or the like can be used. Here, an example of the case where a single crystal silicon substrate is used as the substrate 200 including a semiconductor material will be described.

Note that in general, the term “SOI substrate” means a substrate where a silicon semiconductor layer is provided on an insulating surface. In this specification and the like, the term “SOI substrate” also includes a substrate where a semiconductor layer formed using a material other than silicon is provided over an insulating surface in its category. That is, a semiconductor layer included in the “SOI substrate” is not limited to a silicon semiconductor layer. Moreover, the SOI substrate also includes a substrate having a structure in which a semiconductor layer is provided over an insulating substrate such as a glass substrate with an insulating layer interposed therebetween.

It is preferable to use a single crystal semiconductor substrate such as a single crystal silicon substrate as the substrate 200 including a semiconductor material because the transistor 260 can operate at higher speed.

A protective layer 202 serving as a mask for forming element isolation insulating layers is formed over the substrate 200 (see FIG. 6A). As the protective layer 202, an insulating layer including a material such as silicon oxide, silicon nitride, or silicon oxynitride can be used, for example. Note that before and after this step, an impurity atom imparting n-type conductivity or an impurity atom imparting p-type conductivity can be added to the substrate 200 in order to control the threshold voltage of the transistor. When the semiconductor material included in the substrate 200 is silicon, phosphorus, arsenic, or the like can be used as the impurity imparting n-type conductivity, and boron, aluminum, gallium, or the like can be used as the impurity imparting p-type conductivity, for example.

Next, part of the substrate 200 in a region which is not covered with the protective layer 202 (i.e., an exposed region) is removed by etching with the use of the protective layer 202 as a mask. Thus, a semiconductor region 204 which is apart from another semiconductor region is formed (see FIG. 6B). As the etching, dry etching is preferably employed, but wet etching may be employed. An etching gas and an etchant can be selected as appropriate in accordance with a material of a layer to be etched.

Then, an insulating layer is formed so as to cover the semiconductor region 204, and the insulating layer in a region which overlaps with the semiconductor region 204 is selectively removed, so that the element isolation insulating layer 206 is formed (see FIG. 6C). The insulating layer is formed using silicon oxide, silicon nitride, silicon oxynitride or the like. As a method for removing the insulating layer, polishing treatment such as chemical mechanical polishing (CMP), etching treatment, or the like can be given, and any of the above treatments may be used alone or in combination. Note that the protective layer 202 is removed after the formation of the semiconductor region 204 or after the formation of the element isolation insulating layer 206.

Note that as a formation method of the element isolation insulating layer 206, a method in which an insulating region is formed by introduction of oxygen or the like can be used as well as the method in which an insulating layer is selectively removed.

Next, an insulating layer is formed on a surface of the semiconductor region 204, and a layer including a conductive material is formed over the insulating layer.

The insulating layer is to be a gate insulating layer later, and may be formed by heat treatment (thermal oxidation treatment or thermal nitridation treatment) on the surface of the semiconductor region 204, for example. High-density plasma treatment may be employed instead of heat treatment. The high-density plasma treatment can be performed using, for example, a mixed gas of a rare gas such as He, Ar, Kr, or Xe and any of oxygen, nitrogen oxide, ammonia, nitrogen, and hydrogen. Needless to say, the insulating layer may be formed by a CVD method, a sputtering method, or the like. The insulating layer preferably has a single-layer structure or a stacked-layer structure including a film which contains any of silicon oxide, silicon oxynitride, silicon nitride, hafnium oxide, aluminum oxide, tantalum oxide, yttrium oxide, hafnium silicate (HfSiₓO_{y} (x>0, y>0)), hafnium silicate (HfSiₓO_{y} (x>0, y>0)) to which nitrogen is added, hafnium aluminate (HfAlₓO_{y} (x>0, y>0)) to which nitrogen is added, and the like. The insulating layer can have a thickness of, for example, 1 nm to 100 nm inclusive, preferably 10 nm to 50 nm inclusive.

The layer including a conductive material can be formed using a metal material such as aluminum, copper, titanium, tantalum, or tungsten. The layer including a conductive material may be formed using a semiconductor material such as polycrystalline silicon. There is no particular limitation on the formation method of the layer including a conductive material, and a variety of film formation methods such as an evaporation method, a CVD method, a sputtering method, or a spin coating method can be employed. Note that this embodiment shows an example of the case where the layer including a conductive material is formed using a metal material.

After that, the insulating layer and the layer including a conductive material are selectively etched, so that the gate insulating layer 208 and the gate electrode 210 are formed (see FIG. 6C).

Next, phosphorus (P), arsenic (As), or the like is added to the semiconductor region 204, so that the channel formation region 216 and the impurity regions 220 are formed (see FIG. 6D). Note that phosphorus or arsenic is added here in order to form an n-channel transistor; an impurity element such as boron (B) or aluminum (Al) may be added in the case where a p-channel transistor is formed. Here, the concentration of the impurity added can be set as appropriate; the concentration is preferably set high when the size of a semiconductor element is extremely reduced.

Note that a sidewall insulating layer may be formed in the periphery of the gate electrode 210 so that an impurity region in which an impurity element is included at a different concentration may be formed.

Next, a metal layer 222 is formed so as to cover the gate electrode 210, the impurity regions 220, and the like (see FIG. 7A). Any of a variety of film formation methods such as a vacuum evaporation method, a sputtering method, and a spin coating method is applicable as a formation method of the metal layer 222. The metal layer 222 is preferably formed using a metal material that becomes a low-resistance metal compound by reaction with the semiconductor material included in the semiconductor region 204. As such a metal material, titanium, tantalum, tungsten, nickel, cobalt, platinum, or the like can be used, for example.

Next, heat treatment is performed, whereby the metal layer 222 reacts with the semiconductor material. Thus, the metal compound regions 224 which are in contact with the impurity regions 220 are formed (see FIG. 7A). Note that in the case where the gate electrode 210 is formed using polycrystalline silicon or the like, a metal compound region is formed also in a region of the gate electrode 210 which is in contact with the metal layer 222.

As the heat treatment, irradiation with a flash lamp can be employed, for example. Although it is needless to say that another heat treatment method may be used, a method by which heat treatment can be completed in an extremely short time is preferably used in order to improve the controllability of chemical reaction in formation of the metal compound. Note that the metal compound regions are formed by reaction of the metal material with the semiconductor material and have sufficiently high conductivity. The formation of the metal compound regions can sufficiently reduce electric resistance and improve element characteristics. Note that the metal layer 222 is removed after the formation of the metal compound regions 224.

Then, the insulating layer 228 and the insulating layer 230 are formed so as to cover the components formed in the above steps (see FIG. 7B). The insulating layer 228 and the insulating layer 230 can be formed using a material including an inorganic insulating material such as silicon oxide, silicon oxynitride, or aluminum oxide. In particular, the insulating layer 228 and the insulating layer 230 are preferably formed using a low dielectric constant (low-k) material, whereby capacitance caused by an overlap of electrodes or wirings can be sufficiently reduced. Note that a porous insulating layer including any of these materials may be used for the insulating layer 228 and the insulating layer 230. A porous insulating layer has lower dielectric constant than an insulating layer having high density; thus, capacitance due to electrodes or wirings can be further reduced.

In addition, a layer including an inorganic insulating material containing a large amount of nitrogen, such as silicon nitride oxide or silicon nitride, may be included in the insulating layer 228 or the insulating layer 230. Thus, entry of an impurity such as water or hydrogen contained in the material included in the lower transistor 260 into the oxide semiconductor layer 244 of the upper transistor 262 that is formed later can be prevented. Note that in this case, it is difficult to remove the layer including an inorganic insulating material containing a large amount of nitrogen only by CMP treatment performed in a later step; therefore, CMP treatment and etching treatment are preferably used in combination.

For example, silicon oxynitride and silicon oxide can be used for forming the insulating layer 228 and the insulating layer 230, respectively. In this manner, when only an inorganic insulating material containing a large amount of oxygen, such as silicon oxynitride or silicon oxide, is used for forming the insulating layer 228 and the insulating layer 230, CMP treatment can be easily performed on the insulating layer 228 and the insulating layer 230 in a later step.

Note that a stacked-layer structure of the insulating layer 228 and the insulating layer 230 is employed here; however, one embodiment of the invention disclosed herein is not limited thereto. A single-layer structure or a stacked-layer structure including three or more layers can also be used. For example, the following structure may be employed: silicon oxynitride and silicon oxide are used for the insulating layer 228 and the insulating layer 230, respectively, and a silicon nitride oxide film is formed between the insulating layer 228 and the insulating layer 230.

After that, as treatment before formation of the transistor 262, CMP treatment is performed on the insulating layer 228 and the insulating layer 230, so that surfaces of the insulating layer 228 and the insulating layer 230 are planarized and a top surface of the gate electrode 210 is exposed (see FIG. 7C).

The CMP treatment may be performed once or plural times. When the CMP treatment is performed plural times, it is preferable that first polishing be performed at a high polishing rate and is followed by final polishing at a low polishing rate. By combining polishing with different polishing rates, planarity of the surfaces of the insulating layer 228 and the insulating layer 230 can be further improved.

In the case where an inorganic insulating material containing a large amount of nitrogen is included in the stacked-layer structure of the insulating layer 228 and the insulating layer 230, it is difficult to remove the inorganic insulating material only by CMP treatment; therefore, CMP treatment and etching treatment are preferably used in combination. As the etching treatment for the inorganic insulating material containing a large amount of nitrogen, either dry etching or wet etching may be used. However, in view of miniaturization of elements, dry etching is preferably used. In addition, it is preferable that etching conditions (an etching gas, an etchant, an etching time, a temperature, or the like) be set as appropriate so that etching rates of the respective insulating layers are uniform and high etching selectivity with the gate electrode 210 can be obtained. In addition, as an etching gas for dry etching, for example, a substance containing a fluorine atom (trifluoromethane (CHF₃) or the like), a substance containing a fluorine atom to which a rare gas such as helium (He) or argon (Ar) is added, or the like can be used.

When the top surface of the gate electrode 210 is exposed from the insulating layer 230, the top surface of the gate electrode 210 and the surface of the insulating layer 230 are preferably provided in one surface.

Note that an electrode, a wiring, a semiconductor layer, an insulating layer, or the like may be further formed before and after the above steps. For example, an electrode which is connected to part of the metal compound regions 224 and functions as a source or drain electrode of the transistor 260 may be formed. In addition, a multilayer wiring structure in which an insulating layer and a conductive layer are stacked may be employed as a wiring structure, so that a highly-integrated semiconductor device can be realized.

### <Method for Manufacturing Upper Transistor>

Then, a conductive layer is formed over the gate electrode 210, the insulating layer 228, the insulating layer 230, and the like, and the conductive layer is selectively etched, so that the first electrode 242a which functions as a source or drain electrode and the second electrode 242b which functions as a source or drain electrode are formed (see FIG. 8A). The first electrode 242a and the second electrode 242b can be formed using a material and a method similar to those of the electrodes which function as source and drain electrodes described in Embodiment 2. Therefore, Embodiment 2 can be referred to for the details.

At this time, the etching is performed so that end portions of the first electrode 242a and the second electrode 242b have tapered shapes. In the case where the end portions of the first electrode 242a and the second electrode 242b have tapered shapes, the end portions can be easily covered by an oxide semiconductor layer to be formed later and disconnection of the oxide semiconductor layer can be prevented. Further, the coverage with a gate insulating layer to be formed later is improved and disconnection of the gate insulating layer can be prevented.

Here, a taper angle is, for example, 30° to 60° inclusive. Note that the taper angle is a tilt angle formed by a side surface and a bottom surface of a layer having a tapered shape (e.g., the first electrode 242a) in the case where the layer is observed from a direction perpendicular to a cross section (a plane perpendicular to the surface of a substrate).

The channel length (L) of the upper transistor is determined by a distance between a lower edge portion of the first electrode 242a and a lower edge portion of the second electrode 242b. Note that for light exposure for forming a mask used in the case where a transistor having a channel length (L) of less than 25 nm is formed, it is preferable to use extreme ultraviolet light whose wavelength is as short as several nanometers to several tens of nanometers. In the light exposure by extreme ultraviolet light, the resolution is high and the depth of focus is large. Therefore, the channel length (L) of the transistor to be formed later can be 10 nm to 1000 nm (1 μm) inclusive, whereby operation speed of a circuit can be increased. Moreover, miniaturization can lead to low power consumption of a semiconductor device.

Here, the first electrode 242a of the transistor 262 and the gate electrode 210 of the transistor 260 are directly connected to each other (see FIG. 8A).

Next, the insulating layer 243a and the insulating layer 243b are formed over the first electrode 242a and the second electrode 242b, respectively (see FIG. 8B). The insulating layer 243a and the insulating layer 243b are formed in the following manner: an insulating layer which covers the first electrode 242a and the second electrode 242b is formed and is selectively etched. The insulating layer 243a and the insulating layer 243b are formed to overlap with part of a gate electrode formed later. When such an insulating layer is provided, the capacitance between the gate electrode and the source or drain electrode can be reduced.

The insulating layer 243a and the insulating layer 243b can be formed using a material including an inorganic insulating material such as silicon oxide, silicon oxynitride, silicon nitride, or aluminum oxide. In particular, a material with a low dielectric constant (a low-k material) is preferably used for forming the insulating layer 243a and the insulating layer 243b, because the capacitance between the gate electrode and the source or drain electrode can be sufficiently reduced. Note that a porous insulating layer formed using such a material may be used as the insulating layer 243a and the insulating layer 243b. A porous insulating layer has a lower dielectric constant than an insulating layer having high density; thus, the capacitance between the gate electrode and the source or drain electrode can be further reduced.

Note that in view of reduction in the capacitance between the gate electrode and the source or drain electrode, the insulating layer 243a and the insulating layer 243b are preferably formed; however, a structure without the insulating layer 243a and the insulating layer 243b may be employed.

Next, an oxide semiconductor layer is formed so as to cover the first electrode 242a and the second electrode 242b, and then the oxide semiconductor layer is selectively etched, so that the oxide semiconductor layer 244 is formed (see FIG. 8C). The oxide semiconductor layer 244 can be formed using a material and a method similar to those of the oxide semiconductor layer described in Embodiment 2. Therefore, Embodiment 2 can be referred to for the details.

Note that as described in Embodiment 2, before the oxide semiconductor layer is formed by a sputtering method, reverse sputtering in which plasma is generated with an argon gas introduced is preferably performed, so that dust attached to a surface on which the oxide semiconductor layer is to be formed (e.g., the surface of the insulating layer 230) is removed.

Heat treatment (first heat treatment) is performed on the formed oxide semiconductor layer. To the method of the heat treatment (the first heat treatment), any of the apparatuses and the methods described in Embodiment 2 can be applied. Therefore, Embodiment 2 can be referred to for the details.

According to the method in which a substance containing a halogen element is introduced into a film formation chamber in a gaseous state during film formation, is reacted with an impurity containing a hydrogen atom which is left remaining in the film formation chamber, is changed to a stable substance containing the hydrogen atom, and is exhausted, the stable substance containing the hydrogen atom is exhausted without providing a metal atom of an oxide semiconductor layer with the hydrogen atom. Therefore, a phenomenon in which a hydrogen atom or the like is taken into the oxide semiconductor layer can be prevented. As a result, a highly purified oxide semiconductor layer can be formed. In the transistor including the i-type (intrinsic) or substantially i-type oxide semiconductor layer in which the residual impurities are reduced, variation in threshold voltage can be suppressed and the off-state current can be reduced, that is, excellent characteristics can be achieved.

Note that the etching of the oxide semiconductor layer may be performed either before or after the heat treatment (the first heat treatment). Although dry etching is preferable in terms of element miniaturization, wet etching may also be used. An etching gas and an etchant can be selected as appropriate in accordance with a material of a layer to be etched. Note that in the case where leakage in an element is not a problem, the oxide semiconductor layer does not have to be processed into an island-shaped oxide semiconductor layer.

Next, the gate insulating layer 246 in contact with the oxide semiconductor layer 244 is formed, and then the gate electrode 248a and the electrode 248b are formed in a region which overlaps with the oxide semiconductor layer 244 and a region which overlaps with the first electrode 242a, respectively, over the gate insulating layer 246 (see FIG. 8D). The gate insulating layer 246 can be formed using a material and a method similar to those of the gate insulating layer described in Embodiment 2.

The formed gate insulating layer 246 is preferably subjected to second heat treatment under an inert gas atmosphere or an oxygen atmosphere. The second heat treatment can be performed in a manner similar to that described in Embodiment 2. The second heat treatment can reduce variation in electric characteristics of the transistor. Further, in the case where the gate insulating layer 246 contains oxygen, oxygen can be supplied to the oxide semiconductor layer 244 to reduce oxygen deficiency in the oxide semiconductor layer 244, so that an i-type (intrinsic) or substantially i-type oxide semiconductor layer can be formed.

Note that in this embodiment, the second heat treatment is performed after the formation of the gate insulating layer 246; the timing of the second heat treatment is not limited thereto. For example, the second heat treatment may be performed after formation of the gate electrode. Alternatively, the second heat treatment may double as the first heat treatment.

The gate electrode 248a can be formed using a material and a method similar to those of the gate electrode 611 described in Embodiment 2. In addition, the electrode 248b can be formed by selectively etching the conductive layer, at the same time as the formation of the gate electrode 248a. Embodiment 2 can be referred to for the details.

Next, the insulating layer 250 and the insulating layer 252 are formed over the gate insulating layer 246, the gate electrode 248a, and the electrode 248b (see FIG. 9A). The insulating layer 250 and the insulating layer 252 can be formed using materials and methods similar to those of the insulating layer 507 and the protective insulating layer 508 described in Embodiment 1. Therefore, Embodiment 1 can be referred to for the details.

Next, an opening which reaches the second electrode 242b is formed in the gate insulating layer 246, the insulating layer 250, and the insulating layer 252 (see FIG. 9B). The opening is formed by selective etching using a mask or the like.

Then, the electrode 254 is formed in the opening, and the wiring 256 in contact with the electrode 254 is formed over the insulating layer 252 (see FIG. 9C).

For example, the electrode 254 can be formed in the following manner: a conductive layer is formed in a region including the opening by a PVD method, a CVD method, or the like, and then, the conductive layer is partly removed by etching treatment, CMP, or the like.

More specifically, it is possible to employ a method, for example, in which a thin titanium film is formed in a region including the openings by a PVD method and a thin titanium nitride film is formed by a CVD method, and then, a tungsten film is formed so as to be embedded in the opening. Here, the titanium film formed by a PVD method has a function of reducing an oxide film (e.g., a natural oxide film) formed on a surface over which the titanium film is formed, to reduce the contact resistance with the lower electrode (here, the second electrode 242b) or the like. The titanium nitride film formed after the formation of the titanium film has a barrier function of preventing diffusion of the conductive material. After a barrier film is formed using titanium, titanium nitride, or the like, a copper film may be formed by plating.

Note that in the case where the electrode 254 is formed by removing part of the conductive layer, it is preferable that a surface of the conductive layer be processed so as to be flat. For example, when a thin titanium film or a thin titanium nitride film is formed in a region including the openings and then a tungsten film is formed so as to be embedded in the opening, excess tungsten, titanium, titanium nitride, or the like can be removed and the planarity of the surface can be improved by subsequent CMP treatment. In the case where the surface including the surface of the electrode 254 is planarized in such a manner, an electrode, a wiring, an insulating layer, a semiconductor layer, and the like can be favorably formed in later steps.

The wiring 256 can be formed using a material and a method similar to those of the wiring including the gate electrode 611 described in Embodiment 2. Embodiment 2 can be referred to for the details.

Through the above steps, the transistor 262 including the highly purified oxide semiconductor layer 244 and the capacitor 264 are completed.

With the use of the highly purified intrinsic oxide semiconductor layer 244, the off-state current of the transistor can be sufficiently reduced. Then, by using such a transistor, a semiconductor device in which memory data can be stored for an extremely long time can be obtained.

Using the method of this embodiment described above as an example, the semiconductor device which includes the lower transistor including a semiconductor material other than an oxide semiconductor and the upper transistor including an oxide semiconductor can be manufactured.

When the gate electrode 210 and the first electrode 242a are directly connected to each other, higher integration of the semiconductor device can be achieved because the contact area can be reduced. Accordingly, storage capacity per unit area of the semiconductor device which can be used as a memory device can be increased.

The structures, methods, and the like described in this embodiment can be combined as appropriate with any of the structures, methods, and the like described in the other embodiments.

### Embodiment 4

In this embodiment, application examples of a semiconductor device according to one embodiment of the invention disclosed herein will be described with reference to FIGS. 10A-1, 10A-2, and 10B. Here, examples of a memory device will be described. Note that in a circuit diagram, “OS” is written beside a transistor in order to indicate that the transistor includes an oxide semiconductor.

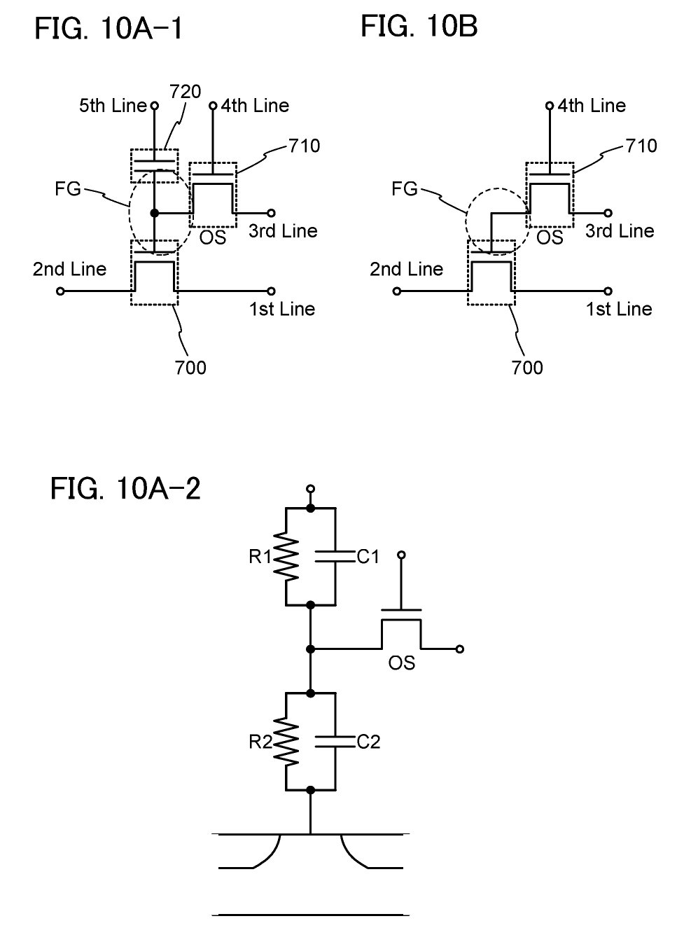

In the semiconductor device illustrated in FIG. 10A-1, a first wiring (a 1st Line) is electrically connected to a source electrode of a transistor 700, and a second wiring (a 2nd Line) is electrically connected to a drain electrode of the transistor 700. A third wiring (a 3rd Line) is electrically connected to one of a source electrode and a drain electrode of a transistor 710, and a fourth wiring (a 4th Line) is electrically connected to a gate electrode of the transistor 710. A fifth wiring (a 5th Line) is electrically connected to one of electrodes of a capacitor 720. A gate electrode of the transistor 700 and the other of the source electrode and the drain electrode of the transistor 710 are electrically connected to the other of the electrodes of the capacitor 720.

Here, a transistor including an oxide semiconductor is used as the transistor 710. Here, as the transistor including an oxide semiconductor, for example, the transistor 262 described in the above embodiment can be used. A transistor including an oxide semiconductor has a characteristic of a significantly low off-state current. Therefore, when the transistor 710 is turned off, the potential of the gate electrode of the transistor 700 can be held for an extremely long time. By providing the capacitor 720, holding of charge given to the gate electrode of the transistor 700 and reading of the held data can be easily performed. Here, as the capacitor 720, for example, the capacitor 264 described in the above embodiment can be used.

In addition, a transistor including a semiconductor material other than an oxide semiconductor is used as the transistor 700. As the semiconductor material other than an oxide semiconductor, for example, silicon, germanium, silicon germanium, silicon carbide, gallium arsenide, or the like can be used, and a single crystal semiconductor is preferably used. Alternatively, an organic semiconductor material or the like may be used. A transistor including such a semiconductor material can operate at high speed easily. Here, as the transistor including a semiconductor material other than an oxide semiconductor, for example, the transistor 260 described in the above embodiment can be used.

Alternatively, a structure without the capacitor 720 as illustrated in FIG. 10B can be employed.

The semiconductor device illustrated in FIG. 10A-1 can write, hold, and read data in such a manner that an advantage in that the potential of the gate electrode of the transistor 700 can be held is utilized.

First, writing and holding of data will be described. First, the potential of the fourth wiring is set to a potential at which the transistor 710 is on, so that the transistor 710 is on. Accordingly, the potential of the third wiring is supplied to the gate electrode of the transistor 700 and the capacitor 720. That is, predetermined charge is given to the gate electrode of the transistor 700 (writing). Here, one of two charges supplying different potentials (hereinafter, a charge supplying a low potential is referred to as a charge Q_{L} and a charge supplying a high potential is referred to as a charge Q_{H}) is given to the gate electrode of the transistor 700. Note that charges giving three or more different potentials may be applied to improve a storage capacity. After that, the potential of the fourth wiring is set to a potential at which the transistor 710 is off, so that the transistor 710 is turned off. Thus, the charge given to the gate electrode of the transistor 700 is held (holding).

Since the off-state current of the transistor 710 is significantly low, the charge in the gate electrode of the transistor 700 is held for a long time.

Second, reading of data will be described. When supplying an appropriate potential (reading potential) to the fifth wiring while a predetermined potential (a constant potential) is supplied to the first wiring, the potential of the second wiring varies depending on the amount of charge held in the gate electrode of the transistor 700. This is because in general, when the transistor 700 is an n-channel transistor, an apparent threshold voltage Vₜₕ_{_{—}}_{H} in the case where Q_{H} is given to the gate electrode of the transistor 700 is lower than an apparent threshold voltage Vₜₕ_{_{—}}_{L} in the case where Q_{L} is given to the gate electrode of the transistor 700. Here, an apparent threshold voltage refers to the potential of the fifth wiring, which is needed to turn on the transistor 700. Thus, when the potential of the fifth wiring is set to a potential V₀ that is intermediate potential between Vₜₕ_{_{—}}_{H} and Vₜₕ_{_{—}}_{L}, charge given to the gate electrode of the transistor 700 can be determined For example, in the case where Q_{H} is given in writing, when the potential of the fifth wiring is set to V₀ (>Vₜₕ_{_{—}}_{H}), the transistor 700 is turned on. In the case where Q_{L} is given in writing, even when the potential of the fifth wiring is set to V₀ (<Vₜₕ_{_{—}}_{L}), the transistor 700 remains in an off state. Therefore, the held data can be read from the potential of the second wiring.

Note that in the case where memory cells are arrayed to be used, it is necessary to read data only from an intended memory cell. Thus, in order that data of a predetermined memory cell is read and data of the other memory cells is not read, in the case where the transistors 700 are connected in parallel among the memory cells, a potential at which the transistor 700 is off regardless of a state of the gate electrode, that is, a potential lower than Vₜₕ_{_{—}}_{H} may be supplied to fifth wirings of the memory cells whose data is not to be read. In the case where the transistors 700 are connected in series among the memory cells, a potential at which the transistor 700 is on regardless of the state of the gate electrode, that is, a potential higher than Vₜₕ_{_{—}}_{L} may be supplied to the fifth wirings of the memory cells whose data is not to be read.

Third, rewriting of data will be described. Rewriting of data is performed in a manner similar to that of the above writing and holding of data. That is, the potential of the fourth wiring is set to a potential at which the transistor 710 is on, so that the transistor 710 is turned on. Accordingly, the potential of the third wiring (potential related to new data) is supplied to the gate electrode of the transistor 700 and the capacitor 720. After that, the potential of the fourth wiring is set to a potential at which the transistor 710 is off, so that the transistor 710 is turned off. Accordingly, charge related to new data is given to the gate electrode of the transistor 700.

In the semiconductor device according to the invention disclosed herein, data can be directly rewritten by another writing of data as described above. Therefore, extracting of charge from a floating gate with the use of high voltage needed in a flash memory or the like is unnecessary; thus, a reduction in operation speed, which is attributed to an erasing operation, can be suppressed. In other words, high-speed operation of the semiconductor device can be realized.

Note that the source electrode or the drain electrode of the transistor 710 is electrically connected to the gate electrode of the transistor 700, thereby having a function similar to that of a floating gate of a floating gate transistor used as a nonvolatile memory element. Therefore, a portion in the drawing where the source electrode or the drain electrode of the transistor 710 is electrically connected to the gate electrode of the transistor 700 is called a floating gate portion FG in some cases. When the transistor 710 is off, the floating gate portion FG can be regarded as being embedded in an insulator and thus charge is held in the floating gate portion FG. The amount of off-state current of the transistor 710 including an oxide semiconductor is lower than or equal to one hundred thousandth of the amount of off-state current of a transistor including a silicon semiconductor or the like; thus, loss of the charge accumulated in the floating gate portion FG due to leakage current from the transistor 710 is negligible. That is, with the transistor 710 including an oxide semiconductor, a nonvolatile memory device which can hold data without being supplied with power can be realized.

For example, when the off-state current of the transistor 710 is lower than or equal to 10 zA (1 zA (zeptoampere) is 1×10⁻²¹ A) at room temperature and the capacitance value of the capacitor 720 is approximately 10 fF, data can be held for 10⁴ seconds or longer. Needless to say, the holding time depends on transistor characteristics and the capacitance value.

Further, in that case, the problem of deterioration of a gate insulating film (tunnel insulating film), which is pointed out in a conventional floating gate transistor, does not arise. That is, the deterioration of a gate insulating film due to injection of an electron into a floating gate, which has been conventionally regarded as a problem, can be solved. This means that there is no limit on the number of writing times in principle. Furthermore, high voltage needed for writing or erasing in a conventional floating gate transistor is unnecessary.

The components such as transistors in the semiconductor device in FIG. 10A-1 can be regarded as including a resistor and a capacitor as illustrated in FIG. 10A-2. That is, in FIG. 10A-2, the transistor 700 and the capacitor 720 are each regarded as including a resistor and a capacitor. Note that R1 and C1 denote the resistance value and the capacitance value of the capacitor 720, respectively. The resistance R1 corresponds to the resistance value of the insulating layer included in the capacitor 720. Further, R2 and C2 denote the resistance value and the capacitance value of the transistor 700, respectively. The resistance value R2 corresponds to the resistance value of a gate insulating layer at the time when the transistor 700 is on. The capacitance value C2 corresponds to the capacitance value of so-called gate capacitance (capacitance formed between the gate electrode and each of the source electrode and the drain electrode and capacitance formed between the gate electrode and the channel formation region).

The resistance value (also referred to as effective resistance) between the source electrode and the drain electrode in the case where the transistor 710 is off is denoted by ROS. When R1 and R2 satisfy the relations of R1 ROS and R2 ROS under the condition that gate leakage of the transistor 710 is sufficiently small, a period for holding charge (also referred to as a data retention period) is determined mainly by the off-state current of the transistor 710.

On the other hand, when the above relations are not satisfied, it is difficult to secure a sufficient retention period even if the off-state current of the transistor 710 is sufficiently low. This is because leakage current other than the off-state current of the transistor 710 (e.g., leakage current generated between the source electrode and the gate electrode) is high. Thus, it is preferable that the semiconductor device disclosed in this embodiment satisfy the above relations.

Moreover, C1 and C2 preferably satisfy the relation of C1 C2. This is because if C1 is large, the potential of the fifth wiring can be supplied to the floating gate portion FG efficiently at the time of controlling the potential of the floating gate portion FG by the fifth wiring, and a difference between potentials (e.g., the reading potential and a non-reading potential) supplied to the fifth wiring can be suppressed small.

When the above relation is satisfied, a more favorable semiconductor device can be realized. Note that R1 and R2 are controlled by the gate insulating layer of the transistor 700 and the insulating layer of the capacitor 720. The same can be said to C1 and C2. Therefore, it is preferable that the material, the thickness, and the like of the gate insulating layer be set as appropriate to satisfy the above relations.

In the semiconductor device of this embodiment, the floating gate portion FG has a function equivalent to that of a floating gate of a floating gate transistor in a flash memory or the like, but the floating gate portion FG of this embodiment has an essentially different feature from that of the floating gate of the flash memory or the like. In a flash memory, since a voltage applied to a control gate is high, it is necessary to keep a proper distance between cells in order to prevent the potential from adversely affecting a floating gate of the adjacent cell. This is one of inhibiting factors in high integration of semiconductor devices. The factor is attributed to a basic principle of a flash memory, in which a tunneling current is generated by application of a high electric field.

Further, because of the above principle of a flash memory, deterioration of an insulating film proceeds and thus another problem of the limit on the number of rewriting times (approximately 10⁴ to 10⁵ times) occurs.

The semiconductor device according to the invention disclosed herein operates by switching of a transistor including an oxide semiconductor and does not use the above principle of charge injection by a tunneling current. That is, unlike a flash memory, a high electric field for injection of charge is not necessary. Accordingly, it is not necessary to consider an influence of a high electric field from a control gate on an adjacent cell, which facilitates high integration.

Further, since charge injection by a tunneling current is not utilized, there is no cause for deterioration of a memory cell. In other words, the semiconductor device according to the invention disclosed herein has higher durability and reliability than a flash memory.

In addition, the semiconductor device according to the invention has advantages over a flash memory in that a high electric field is unnecessary and a large peripheral circuit (such as a booster circuit) is unnecessary.

In the case where the dielectric constant ∈r1 of the insulating layer included in the capacitor 720 is different from the dielectric constant ∈r2 of the insulating layer included in the transistor 700, it is easy to satisfy C1≧C2 while 2·S2≧S1 (preferably, S2≧S1) is satisfied where S1 is the area of the insulating layer included in the capacitor 720 and S2 is the area of the insulating layer forming the gate capacitance of the transistor 700. That is, it is easy to satisfy C1≧C2 while it is satisfied that the area of the insulating layer included in the capacitor 720 is small. Specifically, for example, a film formed of a high-k material such as hafnium oxide or a stack including a film formed of a high-k material such as hafnium oxide and a film formed of an oxide semiconductor is used for the insulating layer included in the capacitor 720 so that ∈r1 can be set to 10 or more, preferably 15 or more, and silicon oxide is used for the insulating layer forming the gate capacitance so that ∈r2 can be set to 3 to 4.

A combination of such structures enables higher integration of the semiconductor device according to the invention disclosed herein.

Note that an n-channel transistor in which electrons are majority carriers is used in the above description; it is needless to say that a p-channel transistor in which holes are majority carriers can be used instead of the n-channel transistor.

As described above, the semiconductor device according to one embodiment of the invention disclosed herein has a non-volatile memory cell that includes a writing transistor in which leakage current between a source and a drain in an off state (off-state current) is small, a reading transistor including a semiconductor material different from that of the writing transistor, and a capacitor.

The off-state current of the writing transistor is preferably lower than or equal to 100 zA (1×10⁻¹⁹ A), further preferably less than or equal to 10 zA (1×10⁻²⁰ A), still further preferably less than or equal to 1 zA (1×10⁻²¹ A) at ambient temperature (e.g., 25° C.). In the case of a general silicon semiconductor, it is difficult to achieve such low off-state current. However, in a transistor obtained by processing an oxide semiconductor under an appropriate condition, low off-state current can be achieved. Therefore, a transistor including an oxide semiconductor is preferably used as the writing transistor.

In addition, a transistor including an oxide semiconductor has a small subthreshold swing (S value), so that the switching rate can be sufficiently high even if mobility is comparatively low. Therefore, by using the transistor as the writing transistor, the rise of a writing pulse given to the floating gate portion FG can be very sharp. Further, since the off-state current is low, the amount of charge held in the floating gate portion FG can be reduced. That is, by using a transistor including an oxide semiconductor as the writing transistor, rewriting of data can be performed at high speed.

Although there is no limitation on the off-state current of the reading transistor, a transistor that operates at high speed is preferably used as the reading transistor in order to increase the readout speed. For example, a transistor having a switching rate of 1 nanosecond or lower is preferably used as the reading transistor.

In this manner, when a transistor including an oxide semiconductor is used as a writing transistor, and a transistor including a semiconductor material other than an oxide semiconductor is used as a reading transistor, a semiconductor device capable of holding data for a long time and reading data at high speed, which can be used as a memory device, can be obtained.

The structures, methods, and the like described in this embodiment can be combined as appropriate with any of the structures, methods, and the like described in the other embodiments.

### Embodiment 5

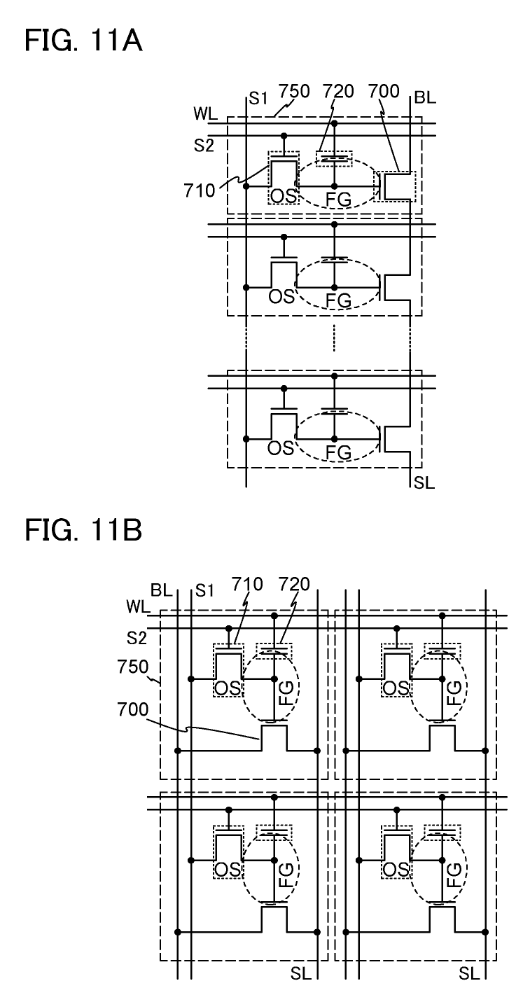

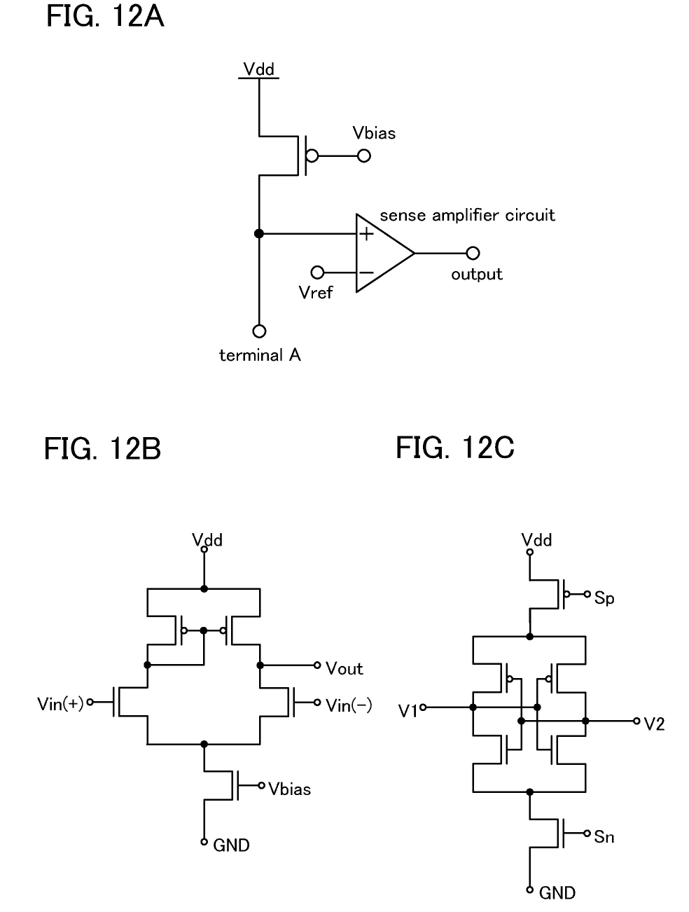

In this embodiment, application examples of a semiconductor device according to one embodiment of the invention disclosed herein will be described with reference to FIGS. 11A and 11B and FIGS. 12A to 12C.

FIGS. 11A and 11B are examples of circuit diagrams of semiconductor devices each including a plurality of semiconductor devices (hereinafter also referred to as memory cells 750) illustrated in FIG. 10A-1. FIG. 11A is a circuit diagram of a so-called NAND semiconductor device in which the memory cells 750 are connected in series. FIG. 11B is a circuit diagram of a so-called NOR semiconductor device in which the memory cells 750 are connected in parallel.

The semiconductor device in FIG. 11A includes a source line SL, a bit line BL, a first signal line S1, a plurality of second signal lines S2, a plurality of word lines WL, and the plurality of memory cells 750. In FIG. 11A, one source line SL and one bit line BL are provided; however, this embodiment is not limited to this structure. A plurality of source lines SL and a plurality of bit lines BL may be provided.

In each of the memory cells 750, a gate electrode of a transistor 700, the other of a source electrode and a drain electrode of a transistor 710, and the other of electrodes of a capacitor 720 are electrically connected to one another. The first signal line S1 and one of the source electrode and the drain electrode of the transistor 710 are electrically connected to each other, and the second signal line S2 and the gate electrode of the transistor 710 are electrically connected to each other. The word line WL and one of the electrodes of the capacitor 720 are electrically connected to each other.

Further, the source electrode of the transistor 700 included in the memory cell 750 is electrically connected to the drain electrode of the transistor 700 in an adjacent memory cell 750. The drain electrode of the transistor 700 included in the memory cell 750 is electrically connected to the source electrode of the transistor 700 in an adjacent memory cell 750. Note that the drain electrode of transistor 700 included in the memory cell 750 at one end among the plurality of memory cells connected in series is electrically connected to the bit line. The source electrode of the transistor 700 included in the memory cell 750 at the other end among the plurality of memory cells connected in series is electrically connected to the source line.

In the semiconductor device illustrated in FIG. 11A, a writing operation and a reading operation are performed per row. The writing operation is performed as follows. A potential at which the transistor 710 is on is applied to the second signal line S2 of a row where writing is to be performed, whereby the transistor 710 of the row where writing is to be performed is turned on. Accordingly, the potential of the first signal line S1 is supplied to the gate electrode of the transistor 700 of the specified row, and a predetermined charge is given to the gate electrode. In this manner, data can be written to the memory cell of the specified row.

Further, the reading operation is performed as follows. First, a potential at which the transistor 700 is on regardless of charge given to the gate electrode thereof is supplied to the word lines WL of the rows other than the row where reading is to be performed, so that the transistors 700 of the rows other than the row where reading is to be performed are turned on. Then, a potential (reading potential) at which an on state or an off state of the transistor 700 is determined depending on charge in the gate electrode of transistor 700 is supplied to the word line WL of the row where reading is to be performed. After that, a constant potential is supplied to the source line SL so that a reading circuit (not illustrated) connected to the bit line BL operates. Here, the plurality of transistors 700 between the source line SL and the bit line BL are on except the transistor 700 of the row where reading is to be performed; therefore, conductance between the source line SL and the bit line BL is determined by a state (an on state or an off state) of the transistor 700 of the row where reading is to be performed. The conductance of the transistor 700 in the row where reading is performed varies depending on charge in the gate electrode thereof. Thus, a potential of the bit line BL varies accordingly. By reading the potential of the bit line with the reading circuit, data can be read from the memory cell of the specified row.

The semiconductor device illustrated in FIG. 11B includes a plurality of source lines SL, a plurality of bit lines BL, a plurality of first signal lines S1, a plurality of second signal lines S2, a plurality of word lines WL, and a plurality of memory cells 750. In each memory cell, the gate electrode of the transistor 700, the other of the source electrode and the drain electrode of the transistor 710, and the other of the electrodes of the capacitor 720 are electrically connected to one another. The source line SL and the source electrode of the transistor 700 are electrically connected to each other. The bit line BL and the drain electrode of the transistor 700 are electrically connected to each other. The first signal line S1 and one of the source electrode and the drain electrode of the transistor 710 are electrically connected to each other, and the second signal line S2 and the gate electrode of the transistor 710 are electrically connected to each other. The word line WL and one of the electrodes of the capacitor 720 are electrically connected to each other.

In the semiconductor device illustrated in FIG. 11B, a writing operation and a reading operation are performed per row. The writing operation is performed in a manner similar to that of the semiconductor device in FIG. 11A. The reading operation is performed as follows. First, a potential at which the transistor 700 is off regardless of charge given to the gate electrode of the transistor 700 is supplied to the word lines WL of the rows other than the row where reading is to be performed, so that the transistors 700 of the rows other than the row where reading is to be performed are turned off. Then, a potential (reading potential) at which an on state or an off state of the transistor 700 is determined depending on charge in the gate electrode of the transistor 700 is supplied to the word line WL of the row where reading is to be performed. After that, a constant potential is supplied to the source lines SL so that a reading circuit (not illustrated) connected to the bit lines BL operates. Here, conductance between the source lines SL and the bit lines BL is determined by a state (an on state or an off state) of the transistors 700 of the row where reading is performed. That is, a potential of the bit lines BL varies depending on charge in the gate electrodes of the transistors 700 of the row where reading is performed. By reading the potential of the bit lines with the reading circuit, data can be read from the memory cells of the specified row.

Although the amount of data which can be held in each of the memory cells 750 is one bit in the above description, the structure of the memory device of this embodiment is not limited thereto. The amount of data which is held in each of the memory cells 750 may be increased by setting three or more levels of potentials supplied to the gate electrode of the transistor 700. For example, in the case where four levels of potentials are supplied to the gate electrode of the transistor 700, data of two bits can be stored in each of the memory cells.

Next, examples of a reading circuit which can be used for the semiconductor devices in FIGS. 11A and 11B or the like will be described with reference to FIGS. 12A to 12C.

FIG. 12A schematically illustrates a reading circuit. The reading circuit includes a transistor and a sense amplifier circuit.

At the time of reading of data, a terminal A is connected to a bit line to which a memory cell from which data is read is connected. Further, a bias potential V_{bias} is applied to a gate electrode of the transistor so that a potential of the terminal A is controlled.

The resistance of the memory cell 750 varies depending on stored data. Specifically, when the transistor 700 in a selected memory cell 750 is on, the memory cell has a low resistance; whereas when the transistor 700 in a selected memory cell 750 is off, the memory cell has a high resistance.

When the memory cell has a high resistance, the potential of the terminal A is higher than a reference potential V_{ref} and the sense amplifier circuit outputs a potential corresponding to the potential of the terminal A. On the other hand, when the memory cell has a low resistance, the potential of the terminal A is lower than the reference potential V_{ref} and the sense amplifier circuit outputs a potential corresponding to the potential of the terminal A.

Thus, by using the reading circuit, data can be read from the memory cell. Note that the reading circuit of this embodiment is one of examples. Another circuit may be used. The reading circuit may further include a precharge circuit. Instead of setting the reference potential V_{ref}, a reference bit line may be connected to the sense amplifier circuit.

FIG. 12B illustrates a differential sense amplifier which is an example of sense amplifier circuits. The differential sense amplifier has input terminals Vᵢₙ(+) and Vᵢₙ(−), and an output terminal Vₒᵤₜ, and amplifies the difference between Vᵢₙ(+) and Vᵢₙ(−). Vₒᵤₜ is approximately high output when Vᵢₙ(+)>Vᵢₙ(−), and is approximately low output when Vᵢₙ(+)<Vᵢₙ(−). In the case where the differential sense amplifier is used for the reading circuit, one of Vᵢₙ (+) and Vᵢₙ (−) is connected to the input terminal A, and the reference potential V_{ref} is supplied to the other of Vᵢₙ (+) and Vᵢₙ (−).

FIG. 12C illustrates a latch sense amplifier which is an example of sense amplifier circuits. The latch sense amplifier has input-output terminals V1 and V2 and input terminals of control signals Sp and Sn. First, the control signals Sp and Sn are set to a signal High and a signal Low, respectively, and a power supply potential (V_{dd}) is interrupted. Then, potentials to be compared are applied to V₁ and V₂. After that, the control signals Sp and Sn are set to a signal Low and a signal High, respectively, and a power supply potential (V_{dd}) is supplied. If the relation V₁ᵢₙ>V₂ᵢₙ is satisfied for the potentials for comparison V₁ᵢₙ and V₂ᵢₙ, an output from V₁ is a signal High and an output from V₂ is a signal Low, whereas an output from V₁ is a signal Low and an output from V₂ is a signal High if the relation V₁ᵢₙ<V₂ᵢₙ is satisfied. By utilizing such relations, the difference between V₁ᵢₙ and V₂ᵢₙ can be amplified. In the case where the latch sense amplifier is used for the reading circuit, one of V₁ and V₂ is connected to the terminal A and the output terminal through a switch, and the reference potential V_{ref} is supplied to the other of V₁ and V₂.

The structures, methods, and the like described in this embodiment can be combined as appropriate with any of the structures, methods, and the like described in the other embodiments.

### Embodiment 6

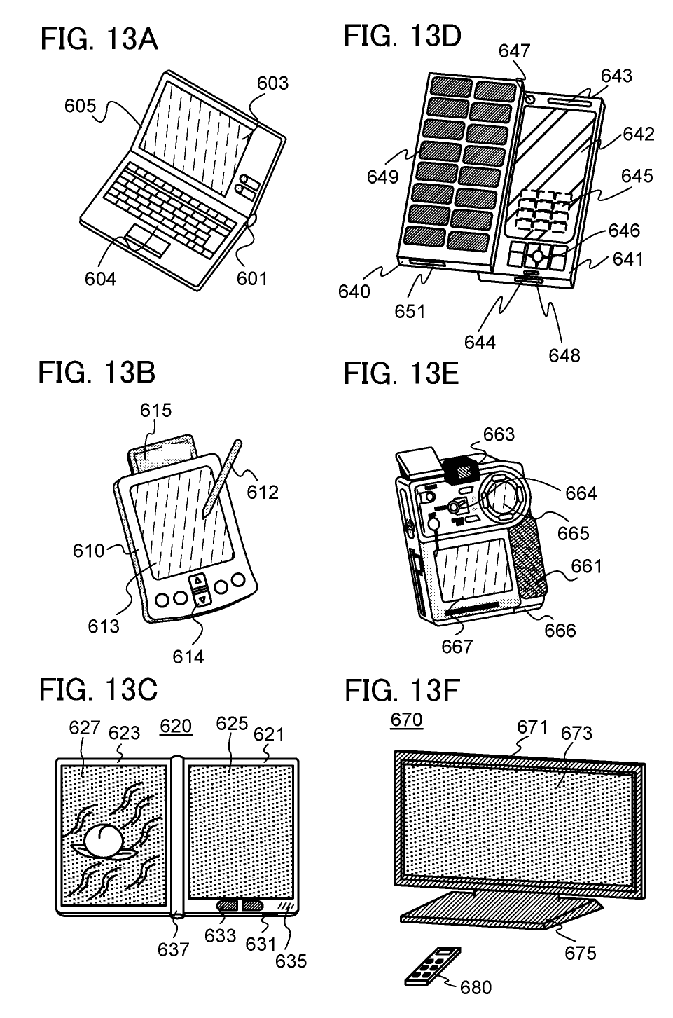

In this embodiment, application of the semiconductor device described in any of the above embodiments to an electronic device will be described with reference to FIGS. 13A to 13F. In this embodiment, cases where the above semiconductor device is applied to electronic devices such as a computer, a mobile phone (also referred to as a mobile telephone or a mobile telephone device), a portable information terminal (including a portable game machine, an audio reproducing device, and the like), a camera such as a digital camera or a digital video camera, an electronic paper, or a television device (also referred to as a television or a television receiver) will be described.

FIG. 13A illustrates a laptop personal computer which includes a housing 601, a housing 605, a display portion 603, a keyboard 604, and the like. In the housing 601 and the housing 605, the semiconductor device of any of the above embodiments which includes a combination of a transistor including an oxide semiconductor and a transistor including a semiconductor material other than an oxide semiconductor is provided. Therefore, the laptop personal computer capable of holding data for a long time and reading data at high speed can be obtained.

FIG. 13B illustrates a portable information terminal (personal digital assistance (PDA)) which includes a main body 610 provided with a display portion 613, an external interface 615, operation buttons 614, and the like. In addition, a stylus 612 which controls the portable information terminal and the like are provided. In the main body 610, the semiconductor device of any of the above embodiments which includes a combination of the transistor including an oxide semiconductor and a transistor including a semiconductor material other than an oxide semiconductor is provided. Therefore, the portable information terminal capable of holding data for a long time and reading data at high speed can be obtained.

FIG. 13C illustrates an electronic book reader 620 which is mounted with electronic paper and includes two housings, a housing 621 and a housing 623. The housing 621 and the housing 623 are provided with a display portion 625 and a display portion 627, respectively. The housing 621 is connected to the housing 623 by a hinge 637, so that the electronic book reader 620 can be opened and closed using the hinge 637 as an axis. The housing 621 is provided with a power button 631, operation keys 633, a speaker 635, and the like. In at least one of the housing 621 and the housing 623, the semiconductor device of any of the above embodiments which includes a combination of a transistor including an oxide semiconductor and a transistor including a semiconductor material other than an oxide semiconductor is provided. Therefore, the electronic book reader capable of holding data for a long time and reading data at high speed can be obtained.

FIG. 13D illustrates a mobile phone which includes two housings, a housing 640 and a housing 641. Moreover, the housing 640 and the housing 641 developed as illustrated in FIG. 13D can be slid so that one is lapped over the other. Therefore, the size of the mobile phone can be reduced, which makes the mobile phone suitable for being carried around. The housing 641 includes a display panel 642, a speaker 643, a microphone 644, a pointing device 646, a camera lens 647, an external connection terminal 648, and the like. The housing 640 includes a solar cell 649 for charging the mobile phone, an external memory slot 651, and the like. The display panel 642 is provided with a touch-panel function. A plurality of operation keys 645 which are displayed as images is illustrated by dashed lines in FIG. 13D. In addition, an antenna is incorporated in the housing 641. In at least one of the housing 640 and the housing 641, the semiconductor device of any of the above embodiments which includes a combination of a transistor including an oxide semiconductor and a transistor including a semiconductor material other than an oxide semiconductor is provided. Therefore, the mobile phone capable of holding data for a long time and reading data at high speed can be obtained.

FIG. 13E illustrates a digital camera which includes a main body 661, a display portion 667, an eyepiece portion 663, an operation switch 664, a display portion 665, a battery 666, and the like. In the main body 661, the semiconductor device of any of the above embodiments which includes a combination of a transistor including an oxide semiconductor and a transistor including a semiconductor material other than an oxide semiconductor is provided. Therefore, the digital camera capable of holding data for a long time and reading data at high speed can be obtained.

FIG. 13F illustrates a television device 670 which includes a housing 671, a display portion 673, a stand 675, and the like. The television device 670 can operate with an operation switch of the housing 671 or a remote controller 680. In the housing 671 and the remote controller 680, the semiconductor device of any of the above embodiments which includes a combination of a transistor including an oxide semiconductor and a transistor including a semiconductor material other than an oxide semiconductor is provided. Therefore, the television device capable of holding data for a long time and reading data at high speed can be obtained.

As described above, the electronic devices described in this embodiment are each mounted with the semiconductor device according to any of the above embodiments. In this manner, electronic devices having characteristics of small size, high-speed operation, and low power consumption can be realized.

### Embodiment 7

In this embodiment, the probability of a process, in which a substance containing a fluorine atom is introduced into a film formation chamber in a gaseous state, is reacted with moisture which is left remaining in the film formation chamber, and is changed to the stable substance containing the hydrogen atom, is verified by quantum chemistry calculation.

This embodiment focuses on a gas phase reaction of a water molecule and a fluorine radical which is generated from a substance containing a fluorine atom which is exposed to plasma in a film formation chamber. Specifically, a process in which a fluorine radical and a water molecule are reacted with each other to generate hydrogen fluoride was analyzed. Note that in this embodiment, activation energy was obtained using quantum chemistry calculation, and the probability of the reaction was evaluated using the activation energy. As the reaction between a fluorine radical (F) and a water molecule (H₂O), a first reaction, a second reaction, and a third reaction described below were assumed.

The first reaction is shown in Reaction Formula 1. The first reaction is a reaction in which a fluorine radical and a water molecule are reacted with each other to generate a hydroxyl radical (OH) and a hydrogen fluoride molecule (HF).

H₂O+F.→.OH+HF [Chemical Formula 1]

The second reaction is shown in Reaction Formula 2. The second reaction is a reaction in which a fluorine radical and the hydroxyl radical (.OH) are reacted with each other to bond a fluorine atom to an oxygen atom to which a hydrogen atom has bonded.

.OH+F.→HOF [Chemical Formula 2]

The third reaction is shown in Reaction Formula 3. The third reaction is a reaction in which a fluorine radical and a substance in which a hydrogen atom and a fluorine atom are bonded to an oxygen atom (HOF) are reacted with each other to generate a radical in which the fluorine atom and the oxygen atom are bonded to each other (FO.), and a hydrogen fluoride molecule (HF).

HOF+F.→FO.+HF [Chemical Formula 3]

Note that the density functional theory (DFT) using Gaussian basis was employed for the calculation. Also in the DFT, an exchange-correlation interaction is approximated by a functional (that is, a function of another function) of one electron potential represented in terms of electron density to enable high-speed and highly-accurate calculations. Here, B3LYP which was a hybrid functional was used to specify the weight of each parameter related to exchange-correlation energy. In addition, as a basis function, 6-311G (a basis function of a triple-split valence basis set using three contraction functions for each valence orbital) was applied to all the atoms. By the above basis function, for example, orbitals of is to 3s are considered in the case of hydrogen atoms while orbitals of is to 4s and 2p to 4p are considered in the case of oxygen atoms. Furthermore, to improve calculation accuracy, the p function and the d function as polarization basis sets were added respectively to hydrogen atoms and atoms other than hydrogen atoms.

Note that Gaussian 09 was used as a quantum chemistry computational program. A high performance computer (Altix 4700, manufactured by SGI Japan, Ltd.) was used for the calculations.

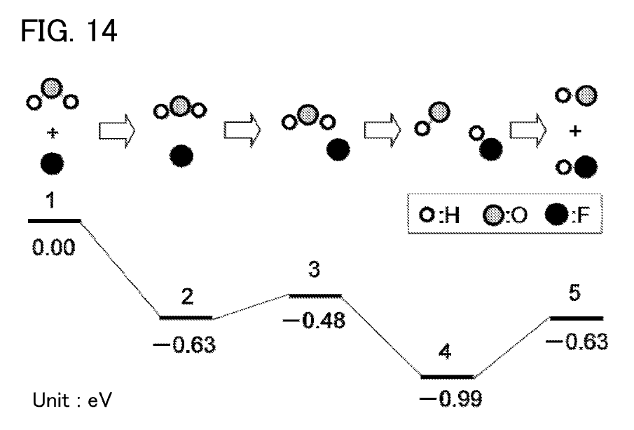

As for the first reaction, an energy diagram of FIG. 14 illustrates a reaction pathway from a first state 1 to a fifth state 5 through a second state 2, a third state 3, and a fourth state 4, and calculated results of energy of respective states.

In the first state 1, a water molecule (H₂O) and a fluorine radical (F) are infinitely apart from each other. Note that the energy of the first state 1 is used as a reference in the energy diagram.

In the second state 2, an intermediate is formed when the water molecule (H₂O) and the fluorine radical (F.) come close to each other. In this state, the potential energy is lower than that of the first state 1 by approximately 0.63 eV due to interaction between the first state 1 and the second state 2.

The third state 3 is a transition state where a hydrogen atom of the water molecule (H₂O) is extracted by the fluorine radical (F), and the activation energy of the reaction of extracting hydrogen was calculated to be 0.15 eV.

In the fourth state 4, an intermediate is formed by the interaction between a generated hydroxyl radical (.OH) and a hydrogen fluoride molecule (HF).

In the fifth state 5, the hydroxyl radical (.OH) and the hydrogen fluoride molecule (HF) are infinitely apart from each other.

In the first reaction, the activation energy of the third state 3 is as low as 0.15 eV, which indicates that there is a high probability that the reaction of extracting hydrogen by the fluorine radical (F.) occurs easily. In addition, the entire first reaction is an exothermal reaction, which tends to progress spontaneously.

In the second reaction, a fluorine radical (F.) and the hydroxyl radical (.OH) are bonded to each other without forming an activation bather. The bonding energy between a fluorine atom and an oxygen atom was calculated to be 2.11 eV.

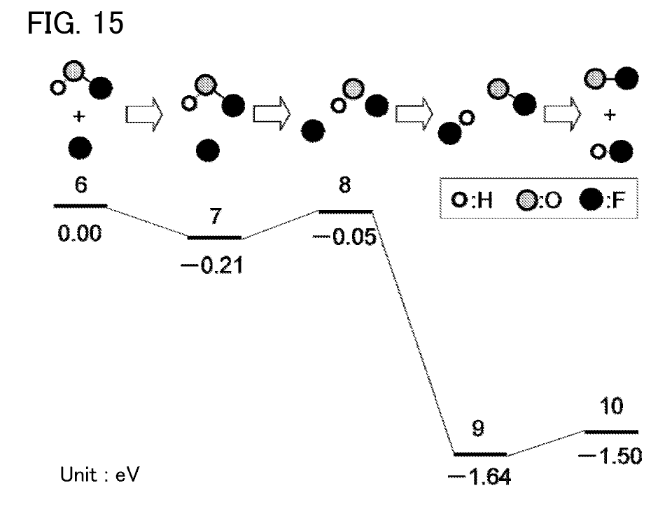

As for the third reaction, FIG. 15 illustrates a reaction pathway from a sixth state 6 to a tenth state 10 through a seventh state 7, an eighth state 8, and a ninth state 9, and analyzed results of energy diagram.

In the sixth state 6 of the third reaction, a substance in which a hydrogen atom and a fluorine atom are bonded to an oxygen atom (HOF) and a fluorine radical (F.) are infinitely apart from each other. Note that the energy of the sixth state 6 is used as a reference in the energy diagram.

In the seventh state 7, an intermediate is formed when the substance in which the hydrogen atom and the fluorine atom are bonded to the oxygen atom (HOF) and the fluorine radical (F) come close to each other. In this state, the potential energy is lower than that of the sixth state 6 by approximately 0.21 eV due to interaction between the substance in which the hydrogen atom and the fluorine atom are bonded to the oxygen atom (HOF) and the fluorine radical (F.).

The eighth state 8 is in a transition state where the hydrogen atom of the substance in which the hydrogen atom and the fluorine atom are bonded to the oxygen atom (HOF) is extracted by the fluorine radical (F.), and the activation energy of the reaction of extracting hydrogen was calculated to be 0.16 eV.

In the ninth state 9, an intermediate is formed by the interaction between a radical in which an oxygen atom and a fluorine atom which are generated are bonded to each other (FO.) and a hydrogen fluoride molecule (HF).

In the tenth state 10, the radical in which the oxygen atom and the fluorine atom are bonded to each other (FO.) and the hydrogen fluoride molecule (HF) are infinitely apart from each other.

In the third reaction, the activation energy of the eighth state 8 is as low as 0.16 eV, which indicates that there is a high probability that the reaction of extracting hydrogen due to the fluorine radical (F.) occurs easily. In addition, the entire third reaction is an exothermal reaction, which tends to progress spontaneously.

Note that the bonding energy between the hydrogen atom and the fluorine atom in the hydrogen fluoride molecule (HF) which is generated in the above reaction is 5.82 eV. Accordingly, the hydrogen fluoride molecule (HF) is less likely to be decomposed.

As described above, a fluorine radical (F.) easily extracts a hydrogen atom from a water molecule (H₂O) and forms a hydrogen fluoride molecule (HF). The generated hydrogen fluoride molecule (HF) is less likely to be decomposed and has an effect of suppressing entry of hydrogen into an oxide semiconductor film because a hydrogen atom is supported.

Therefore, entry of hydrogen or a hydrogen atom derived from moisture into the film can be suppressed by forming an oxide semiconductor film while a substance containing a halogen element is introduced into a film formation chamber in a gaseous state.

This embodiment can be combined as appropriate with any of the other embodiments described in this specification.

### Embodiment 8

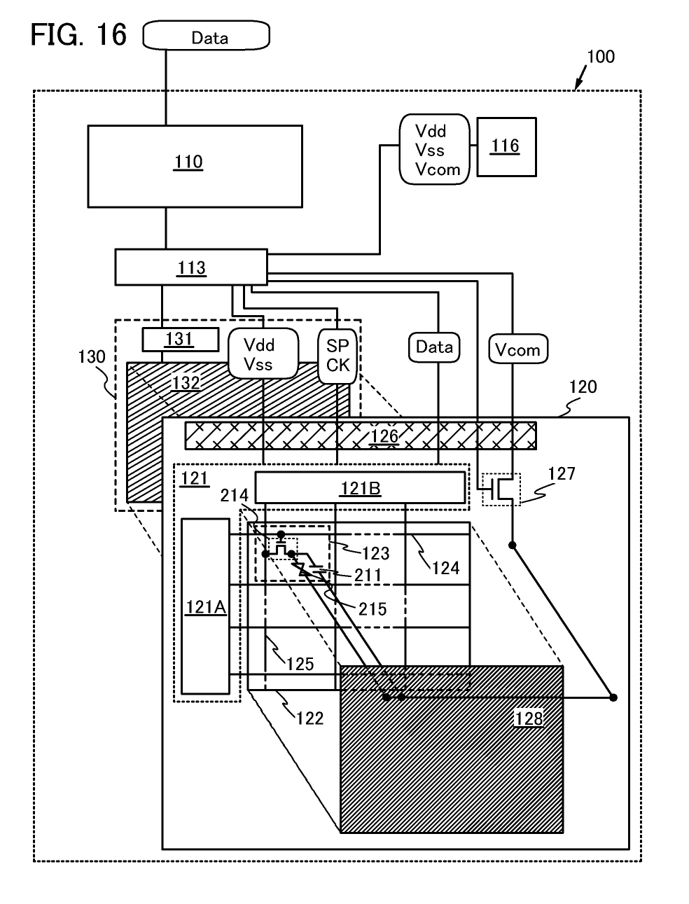

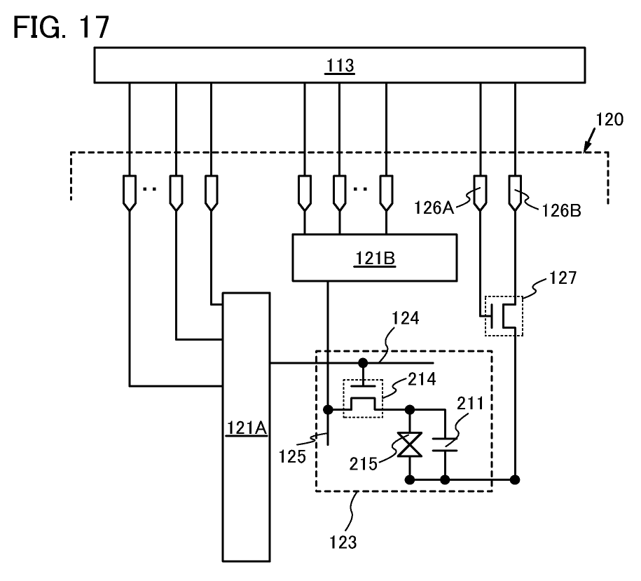

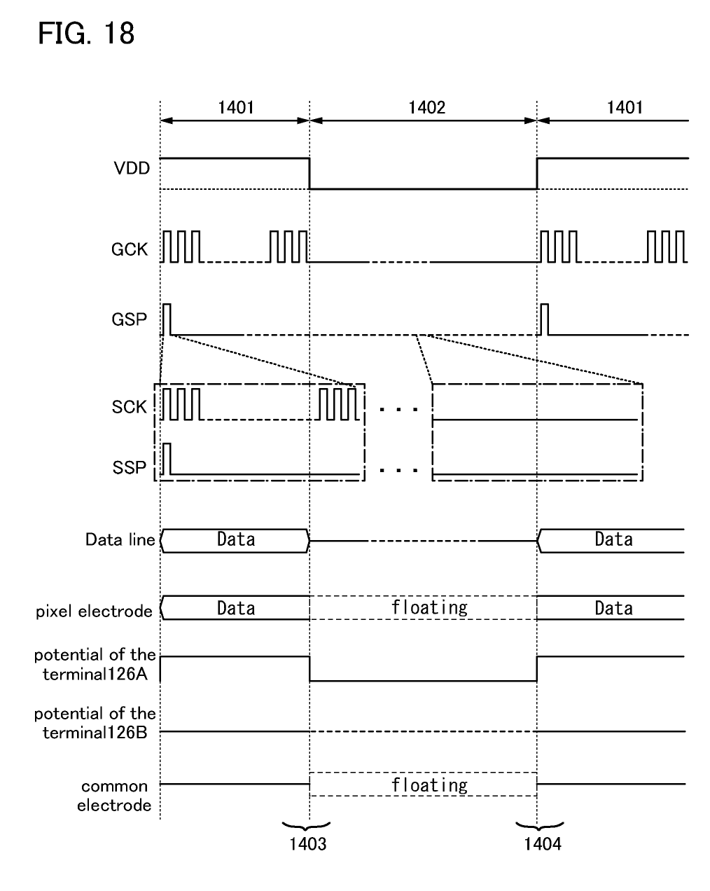

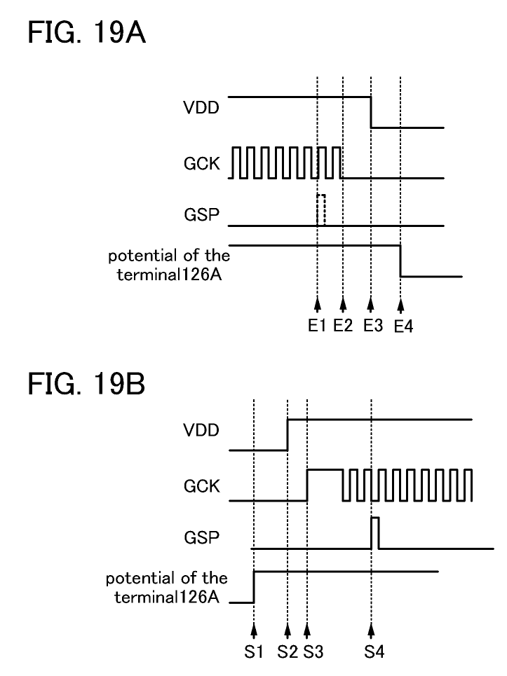

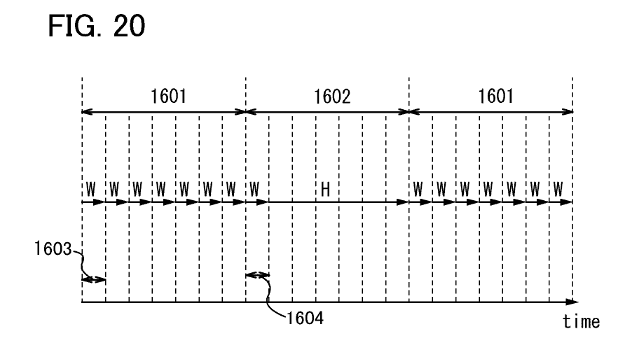

In this embodiment, one embodiment of a liquid crystal display device which can achieve low power consumption and a driving method thereof will be described with reference to FIG. 16, FIG. 17, FIG. 18, FIGS. 19A and 19B, and FIG. 20. A transistor applied to this embodiment is manufactured by a method in which an oxide semiconductor layer is formed while a substance containing a halogen element is introduced into a film formation chamber in a gaseous state and is later subjected to heat treatment to form a highly purified oxide semiconductor layer.

The block diagram of FIG. 16 illustrates components in a liquid crystal display device 100 described in this embodiment. The liquid crystal display device 100 includes an image processing circuit 110, a power supply 116, a display control circuit 113, and a display panel 120. In the case where the liquid crystal display device 100 is a transmissive liquid crystal display device or a transflective liquid crystal display device, a backlight unit 130 is provided as a light source.

An image signal (image signal Data) is supplied to the liquid crystal display device 100 from an external device connected thereto. Power supply potentials (a high power supply potential V_{dd}, a low power supply potential Vₛₛ, and a common potential V_{com}) are supplied to the display control circuit 113 when the power supply 116 is turned on. Control signals (a start pulse SP and a clock signal CK) are supplied by the display control circuit 113.

Note that the high power supply potential V_{dd} is a potential higher than a reference potential, and the low power supply potential Vₛₛ is a potential lower than or equal to the reference potential. Both the high power supply potential V_{ad} and the low power supply potential Vₛₛ are preferably potentials at which a transistor can operate. Note that the high power supply potential V_{dd} and the low power supply potential Vₛₛ may be collectively referred to as a power supply voltage in some cases.

The common potential V_{com} can be any potential as long as it is a fixed potential serving as a reference with respect to a potential of an image signal supplied to a pixel electrode. For example, the common potential V_{com} may be a ground potential.

The image signal Data may be inverted in accordance with dot inversion driving, source line inversion driving, gate line inversion driving, frame inversion driving, or the like as appropriate and inputted to the liquid crystal display device 100. In the case where the image signal Data is an analog signal, such a structure that the image signal is converted into a digital signal by an A/D converter or the like and supplied to the liquid crystal display device 100 is preferably employed.

In this embodiment, the common potential V_{com} which is a fixed potential is supplied to a common electrode 128 and one of electrodes of a capacitor 211 from the power supply 116 through the display control circuit 113.

The display control circuit 113 is a circuit which supplies an image signal processed in the image processing circuit 110, the control signals (specifically, signals for controlling switching between supply and stop of a control signal, such as the start pulse SP and the clock signal CK), and the power supply potentials (the high power supply potential V_{dd}, the low power supply potential Vₛₛ, and the common potential V_{com}) to the display panel 120 and which also supplies a backlight control signal (specifically, a signal with which a backlight control circuit 131 controls on and off of a backlight 132) to the backlight unit 130.

The image processing circuit 110 analyzes, calculates, and/or processes the input image signal (image signal Data) and outputs the processed image signal together with a control signal to the display control circuit 113.

For example, the image processing circuit 110 analyzes the inputted image signal Data and determines whether the signal is for a moving image or a still image, and outputs a control signal including the determination result to the display control circuit 113. Moreover, the image processing circuit 110 can extract data for a one-frame still image from the image signal Data including data for a still image, and output the extracted data to the display control circuit 113, together with a control signal indicating that the extracted data is for a still image. Furthermore, the image processing circuit 110 can sense data for a moving image from the image signal Data including data for a moving image, and output data for successive frames to the display control circuit 113, together with a control signal indicating that the sensed data is for a moving image.

The image processing circuit 110 makes the liquid crystal display device of this embodiment operate in a different manner in accordance with the input image signal Data. In this embodiment, a mode of operation performed when the image processing circuit 110 determines an image as a still image is a still image display mode, whereas a mode of operation performed when the image processing circuit 110 determines an image as a moving image is a moving image display mode. In this specification, an image displayed in the still-image display mode is referred to as a still image.

The image processing circuit 110 described as an example in this embodiment may have a function of switching the display mode. The function of switching the display mode is a function of switching the display mode between a moving image display mode and a still image display mode without a judgment by the image processing circuit 110 in such a manner that a user selects an operation mode of the liquid crystal display device by hand or using an external connection device.

Note that the above function is one example of functions which the image processing circuit 110 has, and a variety of image processing functions may be selected depending on usage of the display device.

Note that since an image signal which is converted to a digital signal is easily calculated (e.g., a difference between image signals is detected), in the case where an input image signal (image signal Data) is an analog signal, an A/D converter or the like can be provided in the image processing circuit 110.

The display panel 120 includes a pair of substrates (a first substrate and a second substrate). A liquid crystal layer is sandwiched between the pair of substrates, and a liquid crystal element 215 is formed. Over the first substrate, a driver circuit portion 121, a pixel portion 122, a terminal portion 126, and a switching element 127 are provided. On the second substrate, the common electrode 128 (also referred to as a common electrode or a counter electrode) is provided. In this embodiment, a common connection portion (also referred to as a common contact) is provided for the first substrate or the second substrate so that a connection portion over the first substrate can be connected to the common electrode 128 on the second substrate.

A plurality of gate lines 124 (scan lines) and a plurality of source lines 125 (signal lines) are provided in the pixel portion 122 and a plurality of pixels 123 are provided in matrix so that the pixels are surrounded by the gate lines 124 and the source lines 125. Note that in the display panel described as an example in this embodiment, the gate lines 124 are extended from a gate line driver circuit 121A, and the source lines 125 are extended from a source line driver circuit 121B.

The pixels 123 each include a transistor 214 as a switching element, and the capacitor 211 and the liquid crystal element 215 which are connected to the transistor 214 (see FIG. 17).

In the transistor 214, a gate electrode is connected to one of the plurality of gate lines 124 provided in the pixel portion 122, one of a source electrode and a drain electrode is connected to one of the plurality of source lines 125, and the other of the source electrode and the drain electrode is connected to one of the electrodes of the capacitor 211 and one of electrodes (a pixel electrode) of the liquid crystal element 215.

As the transistor 214, a transistor whose off-state current is reduced is preferably used; any of the transistors described in Embodiments 1 and 2 is preferable. When the off-state current of the transistor 214 is reduced, charge can be stably held in the liquid crystal element 215 and the capacitor 211 in an off state. In the case where the transistor 214 whose off-state current is sufficiently reduced, the pixel 123 can also be formed without the capacitor 211.

With this configuration, the pixel 123 can maintain the state of data written before the transistor 214 is turned off for a long period, so that power consumption can be reduced.

The liquid crystal element 215 is an element which controls transmission or non-transmission of light utilizing an optical modulation action of liquid crystal. The optical modulation action of liquid crystal is controlled by an electric field applied to the liquid crystal. A direction of the electric field applied to the liquid crystal depends on a liquid crystal material, a driving method, and an electrode structure and can be selected as appropriate. For example, in the case where a driving method in which an electric field is applied in a direction of a thickness of liquid crystal (so-called a vertical direction) is used, a pixel electrode and a common electrode are provided on the first substrate and the second substrate respectively, so that the liquid crystal is interposed between the first substrate and the second substrate. In the case where a driving method in which an electric field is applied in an in-plane direction of a substrate (so-called a horizontal direction) to a liquid crystal is used, a pixel electrode and a common electrode may be provided on the same side with respect to the liquid crystal. The pixel electrode and the common electrode may have a variety of opening patterns.

As examples of a liquid crystal applied to the liquid crystal element, the following can be given: a nematic liquid crystal, a cholesteric liquid crystal, a smectic liquid crystal, a discotic liquid crystal, a thermotropic liquid crystal, a lyotropic liquid crystal, a low-molecular liquid crystal, a polymer dispersed liquid crystal (PDLC), a ferroelectric liquid crystal, an anti-ferroelectric liquid crystal, a main-chain liquid crystal, a side-chain high-molecular liquid crystal, a banana-shaped liquid crystal, and the like.

In addition, any of the following can be used as a driving mode of a liquid crystal: a TN (twisted nematic) mode, an STN (super twisted nematic) mode, an OCB (optically compensated birefringence) mode, an ECB (electrically controlled birefringence) mode, an FLC (ferroelectric liquid crystal) mode, an AFLC (anti-ferroelectric liquid crystal) mode, a PDLC (polymer dispersed liquid crystal) mode, a PNLC (polymer network liquid crystal) mode, a guest-host mode, and the like. Alternatively, an IPS (in-plane-switching) mode, an FFS (fringe field switching) mode, an MVA (multi-domain vertical alignment) mode, a PVA (patterned vertical alignment) mode, an ASM (axially symmetric aligned micro-cell) mode, or the like can be used. Needless to say, there is no particular limitation on a liquid crystal material, a driving method, and an electrode structure in this embodiment as long as the liquid crystal element controls transmission or non-transmission of light by the optical modulation action.

In the liquid crystal element described as an example in this embodiment, the liquid crystal orientation is controlled by an electric field in a vertical direction which is generated between the pixel electrode provided on the first substrate side and the common electrode provided on the second substrate side and facing the pixel electrode.

The terminal portion 126 is an input terminal which supplies predetermined signals (the high power supply potential V_{dd}, the low power supply potential Vₛₛ, the start pulse SP, the clock signal CK, the image signal Data, the common potential V_{com}, and the like) which are outputted from the display control circuit 113, to the driver circuit portion 121.

The driver circuit portion 121 includes the gate line driver circuit 121A and the source line driver circuit 121B. The gate line driver circuit 121A and the source line driver circuit 121B are driver circuits for driving the pixel portion 122 including the plurality of pixels and each include a shift register circuit (also referred to as a shift register).

Note that the gate line driver circuit 121A and the source line driver circuit 121B may be formed over the same substrate as the pixel portion 122 or may be formed over another substrate.

The high power supply potential V_{dd}, the low power supply potential Vₛₛ, the start pulse SP, the clock signal CK, and the image signal Data which are controlled by the display control circuit 113 are supplied to the driver circuit portion 121.

A transistor can be used as the switching element 127. A gate electrode of the switching element 127 is connected to a terminal 126A, and the switching element 127 supplies the common potential V_{com} to the common electrode 128 in accordance with a control signal that is outputted from the display control circuit 113. One of a source electrode and a drain electrode of the switching element 127 may be connected to a terminal 126 B, and the other of the source electrode and the drain electrode may be connected to the common electrode 128 so that the common potential V_{com} is supplied from the display control circuit 113 to the common electrode 128. The switching element 127 may be formed over the same substrate as the driver circuit portion 121 or the pixel portion 122, or may be formed over another substrate.

In addition, by using any of the transistors whose off-state current is reduced described in Embodiments 1 and 2 as the switching element 127, a reduction over time in the voltage applied to both terminals of the liquid crystal element 215 can be suppressed.

The common electrode 128 is electrically connected to a common potential line which supplies the common potential V_{com} controlled by the display control circuit 113 through the common connection portion.

As a specific example of the common connection portion, a conductive particle in which an insulating sphere is covered with a thin metal film is interposed between the common electrode 128 and the common potential line, whereby the common electrode 128 and the common potential line can be electrically connected to each other. Note that a plurality of common connection portions may be provided in the display panel 120.

The liquid crystal display device may include a photometric circuit. The liquid crystal display device provided with the photometric circuit can detect brightness of the environment where the liquid crystal display device is placed. When the photometric circuit detects that the liquid crystal display device is used in a dim environment, the display control circuit 113 controls light from the backlight 132 to have higher intensity so that visibility of the display screen is secured. In contrast, when the photometric circuit detects that the liquid crystal display device is used under extremely bright external light (e.g., under direct sunlight outdoors), the display control circuit 113 controls light from the backlight 132 to have lower intensity so that power consumption of the backlight 132 is reduced. Thus, the display control circuit 113 can control a driving method of a light source such as a backlight or a sidelight in accordance with a signal inputted from the photometric circuit.

The backlight unit 130 includes the backlight control circuit 131 and the backlight 132. The backlight 132 may be selected and combined in accordance with the use of the liquid crystal display device 100. For the backlight 132, a light-emitting diode (LED) or the like can be used. For example, a light-emitting element emitting white light (e.g., an LED) can be provided for the backlight 132. A backlight signal which controls a backlight and a power supply potential are supplied from the display control circuit 113 to the backlight control circuit 131.

If needed, an optical film (such as a polarizing film, a retardation film, or an anti-reflection film) can be used in combination as appropriate. A light source such as a backlight that is used in a semi-transmissive liquid crystal display device may be selected and combined in accordance with the use of the liquid crystal display device 100, and a cold cathode tube, a light-emitting diode (LED), or the like can be used. Further, a surface light source may be formed using a plurality of LED light sources, a plurality of electroluminescent (EL) light sources, or the like. As the surface light source, three or more kinds of LEDs may be used and an LED emitting white light may be used. Note that a color filter is not always provided in the case where light-emitting diodes of RGB or the like are arranged in a backlight and a successive additive color mixing method (a field sequential method) in which color display is performed by time division is employed.

Next, a driving method of the liquid crystal display device 100 illustrated in FIG. 16 will be described with reference to FIG. 17, FIG. 18, FIGS. 19A and 19B, and FIG. 20. The driving method of the liquid crystal display device described in this embodiment is a display method in which the frequency of writing in the display panel varies in accordance with properties of a display image. Specifically, in the case where image signals in successive frames are different from each other (i.e., a moving image is displayed), a display mode in which an image signal is written in each frame period is used. On the other hand, in the case where image signals in successive frames have the same image (i.e., a still image is displayed), a display mode is used in which writing of image signals is not performed or the writing frequency is extremely reduced in a period in which the same image is being displayed; the voltage applied to the liquid crystal element is held by setting potentials of the pixel electrode and the common electrode which apply the voltage to the liquid crystal element in a floating state; and accordingly a still image is displayed without an additional supply of potential.

The liquid crystal display device combines a moving image and a still image and displays images on the screen. The moving image refers to an image which is recognized as an image that is moving by the human eyes by rapidly switching a plurality of different images which are obtained by time division into a plurality of frames. Specifically, by switching images at least 60 times (60 frames) per second, the images are recognized as a moving image with little flicker by the human eyes. In contrast, unlike a moving image and a partial moving image, a still image refers to an image which does not change in successive frame periods, for example, between an n-th frame and an (n+1)-th frame though a plurality of images which are time-divided into a plurality of frame periods are switched at high speed.

First, electric power is supplied by turning on the power supply 116 of the liquid crystal display device. The display control circuit 113 supplies the power supply potentials (the high power supply potential V_{dd}, the low power supply potential Vₛₛ, and the common potential V_{com}) and the control signals (the start pulse SP and the clock signal CK) to the display panel 120.

The image signal (image signal Data) is supplied to the liquid crystal display device 100 from the external device connected thereto. The image processing circuit 110 of the liquid crystal display device 100 analyzes an image signal that is inputted thereto. Here, the case in which whether the image signal is for a moving image or a still image is judged and a different signal is outputted depending on whether the image signal is for a moving image or a still image will be described.

For example, when the input image signal (image signal Data) is switched from a moving image signal to a still image signal, the image processing circuit 110 extracts data for a still image from the inputted image signal, and outputs the extracted data together with a control signal indicating that the extracted data is for a still image to the display control circuit 113. Furthermore, when the inputted image signal (image signal Data) is switched from a still image signal to a moving image signal, the image processing circuit 110 outputs an image signal including data for a moving image together with a control signal indicating that the image signal is for a moving image to the display control circuit 113.

Next, signals supplied to the pixels will be described with reference to an equivalent circuit diagram of the liquid crystal display device illustrated in FIG. 17 and a timing chart shown in FIG. 18.

In FIG. 18, a clock signal GCK and a start pulse GSP that the display control circuit 113 supplies to the gate line driver circuit 121A are shown. In addition, a clock signal SCK and a start pulse SSP that the display control circuit 113 supplies to the source line driver circuit 121B are shown in FIG. 18. To describe output timing of the clock signals, the waveforms of the clock signals are indicated with simple square waves in FIG. 18.

In FIG. 18, a potential of the source line 125, a potential of the pixel electrode, a potential of the terminal 126A, a potential of the terminal 126B, and a potential of the common electrode are illustrated.

In FIG. 18, a period 1401 corresponds to a period during which image signals for displaying a moving image are written. In the period 1401, image signals and a common potential are supplied to each pixel of the pixel portion 122 and the common electrode.

Further, a period 1402 corresponds to a period during which a still image is displayed. In the period 1402, the supply of image signals to each pixel of the pixel portion 122 and the common potential to the common electrode is stopped. Note that FIG. 18 shows a structure in which supply of signals is performed so that the driver circuit portion stops operating during the period 1402; however, it is preferable to employ a structure in which image signals are regularly written depending on the length of the period 1402 and the refresh rate so as to prevent deterioration of a still image.

First, the timing chart in the period 1401 during which image signals for displaying a moving image are written will be described. In the period 1401, a clock signal is always supplied as the clock signal GCK and a pulse corresponding to vertical synchronization frequency is supplied as the start pulse GSP. Moreover, in the period 1401, a clock signal is always supplied as the clock signal SCK and a pulse corresponding to one gate selection period is supplied as the start pulse SSP.

The image signal Data is supplied to the pixels in each row through the source line 125 and a potential of the source line 125 is supplied to the pixel electrode depending on the potential of the gate line 124.

The display control circuit 113 supplies a potential which brings the switching element 127 into electrical conduction to the terminal 126A of the switching element 127 and also supplies a common potential to the common electrode through the terminal 126B.

Next, the timing chart in the period 1402 during which a still image is displayed will be described. In the period 1402, the supply of the clock signal GCK, the start pulse GSP, the clock signal SCK, and the start pulse SSP is stopped. Further, in the period 1402, the supply of the image signal Data to the source line 125 is stopped. In the period 1402 during which the supply of the clock signal GCK and the start pulse GSP is stopped, the transistor 214 is off, and the potential of the pixel electrode becomes in a floating state.

In addition, the display control circuit 113 supplies a potential which brings the switching element 127 out of electrical conduction to the terminal 126A of the switching element 127, so that the potential of the common electrode becomes in a floating state.

In the period 1402, both electrodes of the liquid crystal element 215, i.e., the pixel electrode and the common electrode are put in the floating state; thus, a still image can be displayed without additional supply of potential.

The stop of the supply of a clock signal and a start pulse to the gate line driver circuit 121A and the source line driver circuit 121B enables low power consumption.

In particular, in the case where a transistor whose off-state current is reduced is used for the transistor 214 and the switching element 127, a reduction over time in the voltage applied to both terminals of the liquid crystal element 215 can be suppressed.

Next, operations of the display control circuit in a period during which the displayed image is switched from a moving image to a still image (a period 1403 in FIG. 18) and in a period during which the displayed image is switched from a still image to a moving image (a period 1404 in FIG. 18) will be described with reference to FIGS. 19A and 19B. In FIGS. 19A and 19B, the high power supply potential V_{dd}, the clock signal (here, GCK), the start pulse signal (here, GSP), and the potential of the terminal 126A which are outputted from the display control circuit are shown.

The operation of the display control circuit in the period 1403 during which the displayed image is switched from the moving image to the still image is shown in FIG. 19A. The display control circuit stops the supply of the start pulse GSP (E1 in FIG. 19A, a first step). Then, pulse output reaches the last stage of the shift register after the supply of the start pulse GSP is stopped, and then the supply of a plurality of clock signals GCK is stopped (E2 in FIG. 19A, a second step). Then, the power supply voltage is changed from the high power supply potential V_{dd} to the low power supply potential Vₛₛ (E3 in FIG. 19A, a third step). Next, the potential of the terminal 126A is changed to a potential which brings the switching element 127 out of electrical conduction (E4 in FIG. 19A, a fourth step).

Through the above procedures, the supply of the signals to the driver circuit portion 121 can be stopped without causing a malfunction of the driver circuit portion 121. Since a malfunction generated when the displayed image is switched from a moving image to a still image causes a noise and the noise is held as a still image, a liquid crystal display device mounted with a display control circuit with few malfunctions can display a still image with little image deterioration.

Next, the operation of the display control circuit in the period 1404 during which the displayed image is switched from the still image to the moving image is shown in FIG. 19B. The display control circuit changes the potential of the terminal 126A to a potential which brings the switching element 127 into electrical conduction (S1 in FIG. 19B, a first step). Next, the power supply voltage is changed from the low power supply potential Vₛₛ to the high power supply potential V_{dd} (S2 in FIG. 19B, a second step). Then, a high potential of a pulse signal which has a longer pulse width than the normal clock signal GCK to be supplied later is applied as the clock signal GCK, and then a plurality of normal clock signals GCK are supplied (S3 in FIG. 19B, a third step). Next, the start pulse signal GSP is supplied (S4 in FIG. 19B, a fourth step).

Through the above procedures, the supply of the drive signals to the driver circuit portion 121 can be restarted without causing a malfunction of the driver circuit portion 121. Potentials of the wirings are sequentially changed back to those at the time of displaying a moving image, whereby the driver circuit portion can be driven without causing a malfunction.

FIG. 20 schematically shows writing frequency of image signals in each frame period in a period 1601 during which a moving image is displayed or in a period 1602 during which a still image is displayed. In FIG. 20, “W” indicates a period during which an image signal is written, and “H” indicates a period during which the image signal is held. In addition, a period 1603 in FIG. 20 indicates one frame period; however, the period 1603 may be a different period.

In the structure of the liquid crystal display device of this embodiment, an image signal of a still image displayed in the period 1602 is written in a period 1604, and the image signal written in the period 1604 is held in the other period in the period 1602.

In the liquid crystal display device described as an example in this embodiment, the frequency of writing an image signal in a period during which a still image is displayed can be reduced. As a result, low power consumption at the time of displaying a still image can be achieved.

In the case where the same images are written plural times to display a still image, visual recognition of switching between the images might cause eyestrain. In the liquid crystal display device of this embodiment, the frequency of writing image signals is reduced, whereby there is an effect of making eyestrain less severe.

Specifically, by using any of the transistors whose off-state current is reduced, which are manufactured by a method in which an oxide semiconductor layer is formed while a substance containing a halogen element is introduced into a film formation chamber in a gaseous state and is later subjected to heat treatment to form a highly purified oxide semiconductor layer, for each pixel and a switching element of a common electrode, the liquid crystal display device of this embodiment can have a long period (time) of holding a voltage in a storage capacitor. As a result, the frequency of writing image signals can be remarkably reduced, so that consumed power at the time of displaying a still image can be significantly reduced and eyestrain can be less severe.

This embodiment can be combined as appropriate with any of the other embodiments described in this specification.

This application is based on Japanese Patent Application Serial No. 2010-049602 filed with the Japan Patent Office on Mar. 5, 2010, the entire contents of which are hereby incorporated by reference.

1. A method for manufacturing a semiconductor device comprising the step of:
forming an oxide semiconductor layer for a channel formation region of a transistor in a film formation chamber into which a substance containing a halogen element is introduced in a gaseous state.

2. The method for manufacturing the semiconductor device according to claim 1, further comprising the step of performing heat treatment on the oxide semiconductor layer.

3. The method for manufacturing the semiconductor device according to claim 2,
wherein the oxide semiconductor layer is heated at a temperature of greater than or equal to 250° C. and less than or equal to 700° C., and
wherein the oxide semiconductor layer is heated in nitrogen, oxygen, or a mixed gas of nitrogen and oxygen atmosphere where a content of hydrogen or water is less than or equal to 10 ppm.

4. The method for manufacturing the semiconductor device according to claim 2, further comprising the step of performing slow cooling on the heated oxide semiconductor layer to a temperature of less than or equal to 200° C.

5. The method for manufacturing the semiconductor device according to claim 1, wherein the substance containing a halogen element comprises a fluorine atom.

6. The method for manufacturing the semiconductor device according to claim 1, wherein the oxide semiconductor layer is formed by a sputtering method.

7. A method for manufacturing a semiconductor device comprising the steps of:
forming a gate electrode over a substrate;
forming a gate insulating layer over the gate electrode;
forming an oxide semiconductor layer over the gate insulating layer in a film formation chamber into which a substance containing a halogen element is introduced in a gaseous state; and
forming a source electrode and a drain electrode over the oxide semiconductor layer.

8. The method for manufacturing the semiconductor device according to claim 7, further comprising the step of performing heat treatment on the oxide semiconductor layer.

9. The method for manufacturing the semiconductor device according to claim 8,
wherein the oxide semiconductor layer is heated at a temperature of greater than or equal to 250° C. and less than or equal to 700° C., and
wherein the oxide semiconductor layer is heated in nitrogen, oxygen, or a mixed gas of nitrogen and oxygen atmosphere where a content of hydrogen or water is less than or equal to 10 ppm.

10. The method for manufacturing the semiconductor device according to claim 8, further comprising the step of performing slow cooling on the heated oxide semiconductor layer to a temperature of less than or equal to 200° C.

11. The method for manufacturing the semiconductor device according to claim 7, wherein the substance containing a halogen element comprises a fluorine atom.

12. The method for manufacturing the semiconductor device according to claim 7, further comprising the step of forming a first insulating layer that overlaps with a channel formation region of the oxide semiconductor layer and is in contact with a surface of the oxide semiconductor layer.

13. The method for manufacturing the semiconductor device according to claim 7, wherein the oxide semiconductor layer is formed by a sputtering method.

14. A method for manufacturing a semiconductor device comprising the steps of:
forming a source electrode and a drain electrode over a substrate;
forming an oxide semiconductor layer over the source electrode and the drain electrode in a film formation chamber into which a substance containing a halogen element is introduced in a gaseous state;
forming a gate insulating layer over the oxide semiconductor layer; and
forming a gate electrode over the gate insulating layer.

15. The method for manufacturing the semiconductor device according to claim 14, further comprising the step of performing heat treatment on the oxide semiconductor layer.

16. The method for manufacturing the semiconductor device according to claim 15,
wherein the oxide semiconductor layer is heated at a temperature of greater than or equal to 250° C. and less than or equal to 700° C., and
wherein the oxide semiconductor layer is heated in nitrogen, oxygen, or a mixed gas of nitrogen and oxygen atmosphere where a content of hydrogen or water is less than or equal to 10 ppm.

17. The method for manufacturing the semiconductor device according to claim 15, further comprising the step of performing slow cooling on the heated oxide semiconductor layer to a temperature of less than or equal to 200° C.

18. The method for manufacturing the semiconductor device according to claim 14, wherein the substance containing a halogen element comprises a fluorine atom.

19. The method for manufacturing the semiconductor device according to claim 14, wherein the oxide semiconductor layer is formed by a sputtering method.

20. A semiconductor device comprising:
an oxide semiconductor layer comprising a channel formation region of a transistor,
wherein the oxide semiconductor layer comprises a halogen element, and
wherein a concentration of the halogen element is 10¹⁵ atoms/cm³ to 10¹⁸ atoms/cm³ inclusive.

21. The semiconductor device according to claim 20, wherein the halogen element is a fluorine atom.

22. The semiconductor device according to claim 20, wherein the halogen element is a chlorine atom.
